(19) United States
(12) Patent Application Publication
(10) Pub. No.: US 2022/0246714 A1
(43) Pub. Date: Aug. 4, 2022

(54) LOW TEMPERATURE ROUTE FOR EPITAXIAL INTEGRATION OF PEROVSKITES ON SILICON

(71) Applicants: Drexel University, Philadelphia, PA (US); THE PENN STATE RESEARCH FOUNDATION, University Park, PA (US)

(72) Inventors: Jonathan E. SPANIER, Bala Cynwyd, PA (US); Aleksandr V. PLOKHIKH, Philadelphia, PA (US); Matthias FALMBIGL, Philadelphia, PA (US); Roman ENGEL-HERBERT, University Park, PA (US); Jason LAPANO, University Park, PA (US); Iryna S. GOLOVINA, Philadelphia, PA (US)

(21) Appl. No.: 17/607,726

(22) PCT Filed: Apr. 29, 2020
(86) PCT No.: PCT/US2020/030455

§ 371 Date: Oct. 29, 2021

Related U.S. Application Data
(60) Provisional application No. 62/840,244, filed on Apr. 29, 2019.

(51) Int. Cl. H01L 49/02; H01L 21/02

(52) U.S. Cl. CPC H01L 28/56; H01L 21/02197; H01L 21/02304; H01L 21/02356; H01L 21/0228

(57) ABSTRACT

The present disclosure provides a layering structure that permits integration of epitaxially oriented perovskite oxides, such as bismuth ferrite (BiFeO₃), epitaxially oriented barium titanate (BaTiO₃), epitaxially oriented (SrTiO₃), or their superstructures (BTO/STO) or solid solutions, onto a Si substrate through a perovskite buffer layer. The structure can retain thermal process-sensitive dopant positions and other thermal process window-sensitive features through atomic layer deposition of an oxide perovskite. Also provided are methods of preparing these layered structures.

### CROSS REFERENCE TO RELATED APPLICATIONS

The present application claims priority to and the benefit of U.S. patent application No. 62/840,244, “Low Temperature Route For Epitaxial Integration Of Perovskites On Silicon” (filed Apr. 29, 2019), the entirety of which application is incorporated herein by reference for any and all purposes.

### GOVERNMENT RIGHTS

This invention was made with government support under Grant No. DMR1420620 awarded by the National Science Foundation MRSEC Center for Nanoscale Science at the Pennsylvania State University and Grant No. N00014-15-1-2170 awarded by the Office of Naval Research. The government has certain rights in the invention.

### TECHNICAL FIELD

This disclosure is directed to layering structure that permits integration of epitaxially oriented perovskite oxides.

### BACKGROUND

In recent years, the discovery of novel phenomena and enhancement of ferro- or piezoelectric response in oxide-based perovskite thin films relied heavily on the ability to impart strains onto the films via lattice mismatch and/or a difference in the thermal expansion coefficients compared to an underlying substrate. The ability to grow epitaxial thin films of highest quality exhibiting large misfit strains is useful for the discovery of emerging properties that are not present in the bulk material, e.g., ferroelectricity in SrTiO₃ and CaTiO₃. Accordingly, there is a long-felt need in the art for improved methods of fabricating thin films.

### SUMMARY

This disclosure provides, inter alia, layering structures that permit integration of epitaxially oriented perovskite oxides, such as bismuth ferrite (BiFeO₃), epitaxially oriented barium titanate (BaTiO₃), epitaxially oriented (SrTiO₃), and their superstructures (BTO/STO) and solid solutions, onto a Si surface through a perovskite buffer layer. The structure can retain thermal process-sensitive dopant positions and other thermal process window-sensitive features, through atomic layer deposition of oxides. The approach uses inexpensive and scalable low-temperature and low vacuum deposition method, as explained herein.

Epitaxial thin film growth enables novel functionalities, and the present disclosure addresses existing challenges by, e.g., combining hybrid molecular beam epitaxy and atomic layer deposition to epitaxially integrate a perovskite oxide such as barium titanate (BaTiO₃) and strontium titanate (SrTiO₃), and their superstructures (BTO/STO) and solid solutions, on Si wafers via a metamorphic buffer layer, such as SrTiO₃.

The solid-solid transformation of atomic layer deposited amorphous Bi—Fe—O films into epitaxial BiFeO₃ thin films is illustrated, utilizing in situ annealing in a transmission electron microscope. The amorphous Bi—Fe—O layer undergoes a crystallization process, encompassing phenomena such as reorientation, recrystallization, and grain growth. An in situ TEM study revealed that a m of epitaxial crystallites emerged from the interface with the (001)-oriented SrTiO₃ as temperature increased, while randomly oriented BiFeO₃ crystallites formed simultaneously away from the interface. Structural rearrangement and recrystallization of crystallites took place at temperatures below 400° C.

At the final stage, above 400° C., epitaxial crystallites larger than 60 nm merged into a single crystalline film. These results demonstrated that the disclosed approach provides high quality epitaxial integration of BiFeO₃ thin films at back-end-of-line compatible temperatures below 500° C. on metamorphic SrTiO₃ buffer layers on Si.

The methods for depositing a perovskite oxide disclosed herein can be used with a substrate temperature well below 500° C., for which crystallization occurs well below even 400° C. The method permits deposition indirectly onto, e.g., silicon, which can be used as a bottom electrode, enabling functional oxides for quantum materials/spintronics to be directly integrated onto CMOS and other Si and related technologies via back-end-of-the-line, and possibly front-end-of-the-line procedures. This in turn provides a class of materials that have never before been able to be produced at low temperatures and at scale, and the disclosed approach eliminates the need for separate growth, delamination and transfer, which is not yet shown to be robust for commercial scale.

In meeting the long-felt needs in the art, the present disclosure provides methods for epitaxially integrating a perovskite oxide on a crystalline silicon surface. In one aspect, the present disclosure provides a method for epitaxially integrating a perovskite oxide on a crystalline silicon surface, the method comprising: (a) depositing a crystalline perovskite oxide metamorphic buffer layer onto the crystalline silicon surface; (b) depositing two or more binary metal oxide compounds onto the crystalline perovskite oxide metamorphic buffer layer in order to form a composite structure that includes one or more amorphous metal oxide outer layers on the metamorphic buffer layer; and (c) heating the composite structure for a time and under conditions to allow for the crystallization of each amorphous metal oxide outer layers into an oriented epitaxial perovskite oxide layer.

Also provided are structures, the structures comprising epitaxially integrated perovskite oxide on silicon derived or derivable from the methods of the present disclosure.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various aspects discussed in the present document. In the drawings:

FIG. 1 provides a schematic geometry of the MOS-capacitor used for electrical measurements.

FIG. 2a provides X-ray diffraction of 3 BTOₓ/STO_{y} superstructure films with varying x/y pulse ratios. The stage peak at ˜44.3⁰ is marked with asterisk, and FIG. 2b provides an enlarged range around the (002)-STO substrate peak—the satellite peaks marked with an arrow indicate the diffraction maxima from the superstructure repeat units, and the stage peak is avoided here by using a Si-wafer below the sample.

FIG. 3 provides an XPS depth profile for a BTO₅/STO₅ superstructure with a total number of 6 repeat units and a film thickness of 32 nm. (0 minutes of sputtering corresponds to the film surface, and the sputtering rate is ˜ 0.27 nm/min).

FIG. 4 provides high angle angular dark field scanning transmission electron microscopy images of a BTO₅/STO₅ superstructure with a total number of 8 repeats.

FIG. 5a provides a HAADF STEM images of BTO₃/STO₅, and FIG. 5b provides a HAAFD STEM image of BTO₅/STO₃ superstructures with a total number of 10 repeats.

FIG. 6a provides a selected area and FIG. 6b provides an electron diffraction image taken on a BTO₅/STO₅ superstructure.

FIG. 7 provides a schematic representation of a strained BTOₓ/STO_{y} superlattice grown by ALD. The polarization orientation in the BTO layers is shown.

FIG. 8a provides capacitance and dielectric losses as a function of frequency, and FIG. 8b provides current density as a function of applied bias for three BTOₓ/STO_{y} superstructure films with varying x/y pulse ratios.

FIGS. 9a-9c provide C-V dependences at selected frequencies for a series of 3 BTOₓ/STO_{y} superstructures with varying x/y cycle ratios of 3/5 (FIG. 9a), 5/5 (FIG. 9b), and 5/3 (FIG. 9c).

FIG. 10 provides superstructure repeat unit thickness as a function of increasing BTO or STO cycles for a constant number of 5 repeat cycles for the other constituent.

FIG. 11a provides a selected area and FIG. 11b provides an electron diffraction image taken on a BTO₃/STO₅ superstructure.

FIG. 12a provides 12a selected area and FIG. 12b provides an electron diffraction image taken on a BTO₅/STO₃ superstructure.

FIG. 13 provides indexed SAED image (¼ part) taken on a BTO₅/STO₃ superstructure.

FIG. 14 provides a reciprocal space map of an asymmetric scan around the (103) peak of the SrTiO₃ substrate layer. The dashed line indicates the epitaxial strain of the superlattice to the in-plane lattice dimensions of the substrate layer.

FIG. 15 provides TEM image of the (001) STO-substrate-BFO-film interface collected at a temperature of 250° C. The FFTs of selected areas are displayed on the right, with FFT maxima marked with cyan circles for alpha-Bi₂O₃ (space group: P2₁/C3), arrows in yellow for STO and in orange for BFO, respectively.

FIG. 16a provides TEM image of the (001) STO-substrate-BFO-film interface collected at a temperature of 300° C. The orange line highlights the fraction of (001)-oriented BFO and the red circle marks a region with randomly oriented nanocrystallites with average sizes around 8 nm. FIG. 16b provides a TEM image of a different area showing the initial oriented interfacial layer together with randomly oriented grains closer to the BFO film surface.

FIG. 17a provides an exemplary TEM image of the STO-BFO interface collected at 367° C., and FIG. 17b provides a TEM image of the same region collected 1 minute later at 369° C. The (orange) ellipsoids highlight the area where structural rearrangement was observed; the electron beam remained on between collection of the images.

FIG. 18a provides a TEM image of the STO-BFO interface collected at 382° C., and FIG. 18b provides a TEM image of the same region collected at 385° C. In both cases FFT spectra of the selected area are displayed: on the left spots corresponding to an epitaxially aligned crystallite (orange) and a randomly oriented crystallite (purple) are present. The spots corresponding to the misaligned crystallite vanished at 385° C. (FIG. 18b). The cyan lines mark spots, which might correspond to Bi₂O₃. All indices were provided for cubic symmetry.

FIG. 19a provides a TEM image of the cross section collected at 402° C., and FIG. 19b provides a TEM image collected at the same location at 405° C. The yellow circle marks the area where two large BFO crystallites merge.

FIG. 20a provides a TEM image of the cross section collected at 432° C., and FIG. 20b provides a TEM image collected at the same location at 439° C.

FIG. 21a provides a HAADF-STEM image of a BFO film after ex-situ annealing at 500° C. on a single crystalline (001) STO substrate demonstrating a coherent interface over tenths of nanometers, and FIG. 21b shows a defect area ((red) dashed circle) close to the interface, which interrupts the epitaxial alignment locally.

FIG. 22 provides a 0-20 XRD scans of a 60 nm-thick BiFeO₃ film on a (001)-oriented SrTiO₃/(001)Si substrate after annealing in air at 500° C. # denotes a peak from the Si-substrate. A similar XRD-scan of the 18 nm thick (001)-oriented SrTiO₃ on the (001)-oriented Si-substrate is provided for comparison. The inset shows the 2θ-range around the (002)-diffraction peaks with fittings.

FIG. 23 provides Phi XRD scans of Si(404), SrTiO₃(103) and BiFeO₃(103) measured on a BiFeO₃ film on a (001)-oriented SrTiO₃/(001)Si substrate after annealing in air at 500° C.

### DETAILED DESCRIPTION OF ILLUSTRATIVE EMBODIMENTS

The present disclosure may be understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention.

Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable, and it should be understood that steps can be performed in any order.

It is to be appreciated that certain features of the invention which are, for clarity, described herein in the context of separate embodiments, may also be provided in combination in a single embodiment. Conversely, various features of the invention that are, for brevity, described in the context of a single embodiment, can also be provided separately or in any subcombination. All documents cited herein are incorporated herein in their entireties for any and all purposes.

Further, reference to values stated in ranges include each and every value within that range. In addition, the term “comprising” should be understood as having its standard, open-ended meaning, but also as encompassing “consisting” as well. For example, a device that comprises Part A and Part B can include parts in addition to Part A and Part B, but can also be formed only from Part A and Part B.

Exemplary Disclosure

Provided herein is, inter alia, a pathway for producing epitaxial perovskite superlattices using atomic layer deposition. In one example embodiment, these functional thin films were integrated monolithically on Si-substrates by utilizing a hybrid molecular beam epitaxy (hMBE) process to deposit a crystallization template layer of SrTiO₃ epitaxially on Si(100). In a step, atomic layer deposition is used to obtain fully crystalline epitaxial superlattices; this step was (in one illustrative, non-limiting embodiment) carried out at 360° C., which is well below the temperature limit for CMOS-compatibility. Control over the stacking sequence of different constituents was demonstrated in a series of three (BaTiO₃)ₓ/(SrTiO₃)_{y} superlattices with various x/y cycle ratios. While the interfaces between the BaTiO₃ and SrTiO₃ are not necessarily atomically smooth, all films are coherently strained with the substrate. The unusual electrical properties of the produced metal-oxide-semiconductor capacitors are demonstrated.

Over the last two decades, a number of new effects and exotic phenomena have been theoretically predicted and experimentally demonstrated in ferroelectric artificial heterostructures, and particularly in BaTiO₃/SrTiO₃ (BTO/STO) superlattices. Precise control of the interfacial strain, compositional gradient and/or repetition ratio for constituent sublayers allow to intentionally modify the domain structure and substantially improve the properties or obtain novel functionalities of the material, e.g., emergent interfacial conduction, superconductivity, new ferroelectric order, and magnetic order. From an experimental standpoint, this development was enabled by improvements and innovative approaches in thin-film growth methods on one side, and by systematic advances in analytical instrumentation on the other side.

For epitaxial perovskite oxide superlattices, pulsed laser deposition (PLD), molecular beam epitaxy (MBE) and metal-organic chemical vapor deposition (MOCVD) techniques have been employed. The growth temperatures for (BTO/STO) films utilizing these methods vary from 600° C. (in MBE) to 840° C. (in PLD). Although high-quality epitaxial BTO/STO superlattices can be fabricated, a high thermal budget can prevent the usage of these techniques for commercial applications. Furthermore, a thin-film fabrication technology needs to be integrated into semiconductor industry CMOS platforms as much as possible. For this reason, one may wish to reduce the growth temperature.

Atomic layer deposition (ALD) is a powerful technique that can meet these demands due to a unique combination of arbitrary scalability, conformal coating, and low deposition temperatures. Additionally, while the composition of the PLD-grown film is only macroscopically controlled with high precision in the ceramic target prior to the film growth, an ALD enables the excellent control of the film stoichiometry during the deposition procedure, and so also for complex oxides such as BTO and STO.

Recent studies show that thin epitaxial crystalline ternary oxides, like ABO₃ perovskites, can be successfully integrated on semiconductor substrates (Si, Ge, or GaAs) using the ALD method. This made ALD an alternative to the MBE and PLD techniques. Ngo et. al (Epitaxial c-axis oriented BaTiO3 thin films on SrTiO3-buffered Si(001) by atomic layer deposition. Applied Physics Letters 104, 082910 (2014)) report on epitaxial c-axis oriented BTO films with a reasonable as-deposited crystallinity grown by ALD. For a direct integration on Si(001) substrate, a thin buffer layer of STO grown by MBE was used. The use of MBE grown STO as a template for incorporating other epitaxial oxide films onto Si is used in the field.

However, the growth of epitaxial BTO/STO superlattices on STO/Si virtual substrate has not been demonstrated so far. Provided here are, e.g., fully-crystalline epitaxial (BTO)ₓ/(STO)_{y} superlattices on (001)-oriented STO/Si substrates grown by ALD at a temperature of only 360° C. This growth temperature is significantly lower than the growth temperatures for BTO, STO and BTO/STO superlattices typically used for PLD, MBE, and MOCVD, and well within the range for CMOS-compatible processes. A modified hybrid MBE (hMBE) process provides STO on the templated Si surface without forming an amorphous silicon dioxide layer at the interface. A set of three films with various cycle ratios x/y=3/5, 5/5 and 5/3 were produced and a thorough characterization using X-ray diffraction (XRD), scanning electron microscopy (SEM), high resolution transmission electron microscopy (HR-TEM) and scanning transmission electron microscopy (STEM), X-ray photoelectron spectroscopy (XPS), and reciprocal space mapping (RSM) techniques were performed.

Our approach unambiguously demonstrates obtaining epitaxial BTOₓ/STO_{y} superstructures with various x/y ratios integrated on a Si substrate by using ALD on hMBE-grown STO buffer layers, at a substantially reduced growth temperature. The produced films exhibit low dielectric losses and low leakage current at room temperature. An interesting electric-field dependence of capacitance as a function of frequency is also shown.

As a non-limiting example, a metamorphic 18 nm thick (001)-oriented STO buffer layer was grown using a hybrid molecular beam epitaxy (hMBE) technique described in detail elsewhere. Briefly, the growth of the STO layer was conducted in two steps. First, a 10 monolayer thick template of STO is deposited on an etched (001)-oriented Si substrate at low temperatures (400-600° C.) by co-supplying elemental Sr and the organometallic Ti-precursor, titanium tetra-isopropoxide (TTIP), from a conventional effusion cell and gas injector, respectively. This initial deposition step was performed in the absence of additional oxygen. The Ti in the TTIP molecule is tetrahedrally coordinated by oxygen, which facilitates the formation of STO on the templated Si surface without forming an amorphous silicon dioxide layer at the interface. After the initial layer formation, growth rates and temperatures were increased to about 50 nm/hr at 600-900° C. until a total STO layer thickness of 18 nm was reached.

Atomic layer depositions (ALD) of the BTO/STO superlattices were conducted at 360° C. using Absolut Ba (Air Liquide, Ba(iPr₃Cp)₂), Absolut Sr (Air Liquide, Sr(iPr₃Cp)₂), Ti-tetramethoxide (TMO, Alfa Aesar Ti(OMe)₄, and O₃ as precursors. High purity N₂ gas (Airgas grade Research plus, 99.9999%) was used as carrier gas. The pulse and purge times were 1.6/6 s for Ba(iPr₃Cp)₂ and Sr(iPr₃Cp)₂, 0.1/3 s for TMO, and 0.4/3 s for O₃, respectively. The pulse sequences for the BaTiO₃ subcycle and the SrTiO₃ subcycle were 2×(Ba(iPr₃Cp)₂/Sr(iPr₃Cp)₂+O₃): 3×(TMO+O₃) providing a 1:1:cation ratio for each individual ternary perovskite film. While it was already demonstrated that Sr(iPr₃Cp)₂ is stable at this deposition temperature, the decomposition for Ba(iPr₃Cp)₂ and TMO contribute x and 3% to the total growth rate, respectively. The fraction of the film growth corresponding to decomposition was evaluated by pulsing the organometallic precursors consecutively without pulsing O₃ at a reactor temperature of 360° C., followed by measuring the resulting film thickness on a Si-substrate by X-ray reflectivity (XRR).

XRD and XRR scans were performed on a Rigaku Smartlab using Cu-Kai radiation. The composition was measured using a Zeiss Supra 50 VP Scanning Electron Microscope equipped with an energy-dispersive detector (Oxford Instruments).

Cross-sections of the thin film samples for high resolution transmission electron microscopy (HR-TEM) and scanning transmission electron microscopy (STEM) were prepared in a Helios Nanolab 600i (FEI, USA) Scanning Electron Microscope (SEM)/Focused Ion Beam (FIB) dual beam system equipped with gas injectors for W and Pt deposition and an Omniprobe micromanipulator (Omniprobe, USA). After depositing a 2 m thick protective Pt layer, milling using a 30 keV Ga⁺ ion beam resulted in a cross-section area of 5×5 μm², which was subsequently polished with 5 keV and 2 keV Ga⁺ ion beams, respectively. These cross sections were investigated utilizing a Titan 80-300 operated at 300 kV, which is equipped with a high-angle annular dark-field (HAADF) detector (Fischione, USA), a spherical aberration (Cₛ) probe corrector and a post-column Gatan image filter (GIF). Digital Micrograph (Gatan, USA) and Tecnai Imaging and Analysis (FEI, USA) software were used for the image processing.

XPS measurements were conducted using a Physical Electronics VersaProbe 5000 under a base-pressure of ≈10⁻⁶ Pa. An Al—K_{α} source provided incident photons with an energy of 1486.6 eV at 10 kW mm⁻². The XPS spectra were collected with the pass energy of 23 eV. An electron neutralizer was used to neutralize the surface. Linear energy correction was applied in reference to the carbon spectra. The energy of the Cis peak of non-oxidized carbon was set at 284.8 eV. The detector was placed at the angle of 100 relatively to the surface of the film. In order to resolve the in-depth structure of the film, a stepped fast XPS-measurements between Ar⁺ ion sputtering stages were performed. Ar⁺ ion sputtering procedure was conducted at an accelerated voltage of 1 kV and an ion current of 1 μA per 2 mm×2 mm area at 450 in order to provide controllable and stoichiometric sputtering. The total duration of all sputtering steps was 12 sec. XPS spectra for Ba3d, Sr3d, CIs, O1s, and Si2p bands were collected as the most intensive lines for the Ba, Sr, C, O, and Si respectively. All quantification and spectrum fittings were performed with Casa XPS software using a Shirley type background.

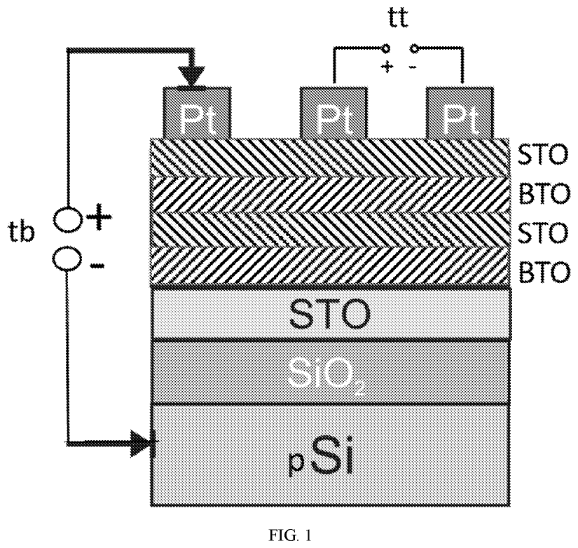

Metal-oxide-semiconductor (MOS) capacitors were produced by depositing ≈80 nm thick 90×90 μm² squares of Pt using a standard photolithography process and magnetron sputtering at room temperature. The electrical properties of the SIM-capacitors were measured in a probe station (Lakeshore Cryotronics TTP4) utilizing a Keithley SCS-4200 electrometer for collecting capacitance, loss tangent and C-V dependences as a function of frequency, from 10 kHz to 1 MHz. Electrical measurements were performed in the top-to-bottom (tb) or top-to-top (tt) geometry, schematically shown in FIG. 1.

In the first step of developing an ALD-process for the growth of BTO/STO superstructures, the ternary oxides, BaTiO₃ and SrTiO₃, were deposited individually under similar growth conditions.

Initially, the pulse ratios were adjusted with the smallest possible repeat numbers of (Ba/Sr)—O and Ti—O to provide stoichiometric cation ratios and thorough intermixing of the cations to facilitate the crystallization of ternary perovskite structures at low temperatures. The growth rates for both constituents were measured individually, providing a growth per ternary cycle (GPC) of 0.58 nm for BTO and 0.46 nm for STO, respectively.

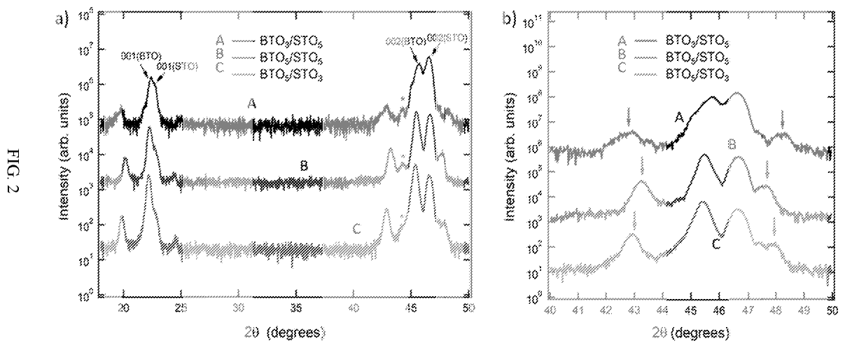

Subsequently, the sub-cycles for BTO and STO were combined in different ratios for each constituent (please, note that we will use the following notation hereafter: (x/y)×z with x and y denoting the number of consecutive BTO- and STO-cycles and not the number of unit cells, and z the number of total repeats) and repeated until a film thickness of ≈40 nm was reached for a set of 3 films. The X-ray diffraction patterns of all samples after deposition are shown in FIG. 2. Remarkably, all patterns reveal high intensity peaks in the vicinity of the only (001)-peaks from the hybrid-MBE-grown 18 nm thick STO film after the deposition at 360° C., indicating crystalline and well oriented ALD films for all selected deposition sequences. No peaks from impurity phases are indicated.

A closer inspection of the diffraction patterns reveals additional satellite peaks arising from the artificial superstructure of alternating BTO and STO layers. While these satellite peaks are not as prominent and continuous as for BTO/STO superlattices with precisely controlled repeat unit thicknesses and abrupt interfaces, they indicate the presence of Ba-rich and Sr-rich alternating layers within the films and can be indexed to the repeat unit thickness (see FIG. 2b and Table 1).

Calculating the c-lattice parameter from the peak positions of the main diffraction peaks for each superstructure results in a range from 3.97 Å to 4.01 Å increasing with the fraction of BTO (Table 1). The cubic lattice parameters of the ternary end members are, STO (a=3.905 Å) and BTO (a_{PC}=4.01 Å). The values for the average c-lattice parameters of the superlattices should represent the average thickness for both constituents and are slightly larger than the expected average value calculated from the end members. Without being bound to any particular theory this difference was expected considering the presence of the tensile strain imparted by the h-MBE grown STO layer onto the ALD-grown BTO-layers.

TABLE 1
Series of 3 superstructures (BTOₓ/STO_{y}) × z with varying (x/y) × z cycle
numbers, c-lattice parameter calculated for the main peak, superstructure
repeat unit thickness, and total film thickness.

| | c-lattice | Superstructure | Total film |
|---|---|---|---|
| (x/y) × z | parameter, Å | thickness, Å | thickness, Å |
| (3/5) × 10 | 3.97 | 39.8 | 406 |
| (5/5) × 8 | 3.99 | 47.9 | 388 |
| (5/3) × 10 | 4.01 | 40.0 | 375 |

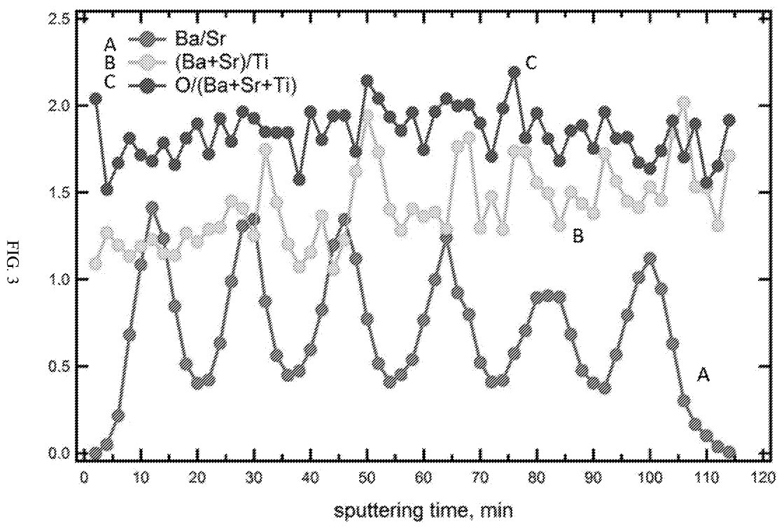

The segregation into a Ba-rich and a Sr-rich constituent layers of the superstructure is further corroborated by an XPS depth profile using Ar-ion sputtering (FIG. 3). Here, a clear oscillation of the Ba/Sr ratio is observed, while the Ti- and O-content exhibit only minor changes. The 6 maxima/minima in the Ba/Sr-ratio are consistent with the deposition sequence for a (BTO₅/STO₅)×6 superstructure.

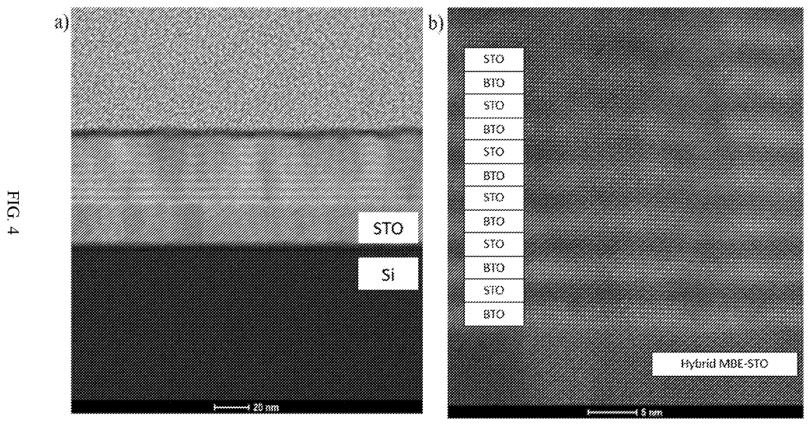

High angle angular dark field (HAADF) STEM images of an exemplary BTO₅/STO₅ superstructure with a total of 8 repeats are shown in FIG. 4. In FIG. 4a a low magnification cross-sectional image reveals the entire layered structure over a large length scale with 8 repeat units of alternating bright (BTO) and dark (STO) layers on the virtual (001)-oriented STO/Si-substrate.

A further review (FIG. 4b) reveals epitaxial and crystalline alternating layers. However, the interfaces between the layers are not atomically sharp and abrupt, but exhibit a wave-like appearance. Unlike superlattices grown by high temperature methods, which typically exhibit atomically sharp interfaces due to a unit cell by unit cell growth mode, the ALD-grown superstructures show this unique feature. The waviness most likely arises from the growth method, which is not adding the exact amount of atoms per pulse to enable a layer per layer growth, but supplies a stoichiometric amount of cations within each subcycle.

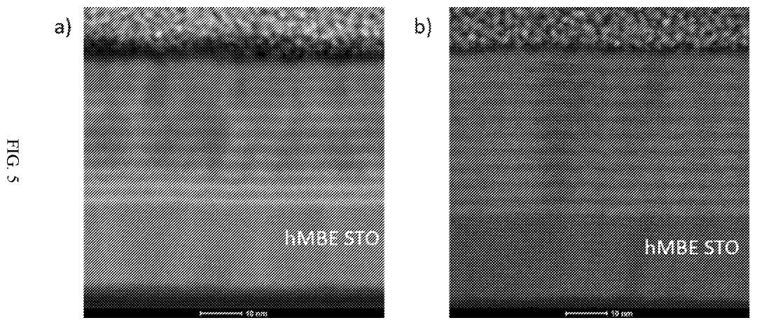

Evidence for this fundamental difference is provided by the average thickness of 0.58 nm/BTO- and 0.46 nm/STO-subcycle, which do not correspond to the unit cell thicknesses. It also arises in part from the interface to the hMBE-grown crystallization template layer, which is not atomically smooth. HAADF STEM images of the BTO₃/STO₅ and BTO₅/STO₃ superstructures with a total of 10 repeats are shown in FIG. 5. For each superstructure, a fully crystalline epitaxial film with alternating BTO and STO sublayers is observed.

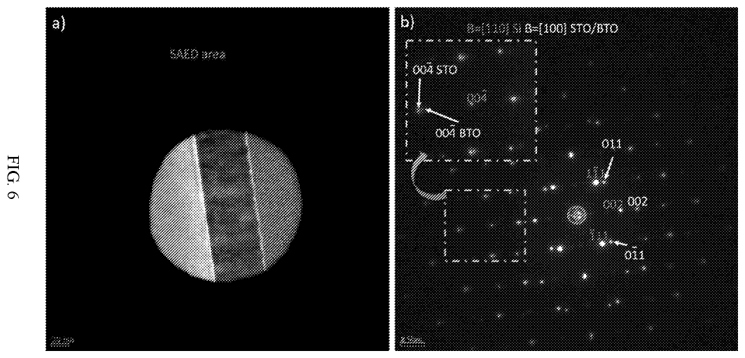

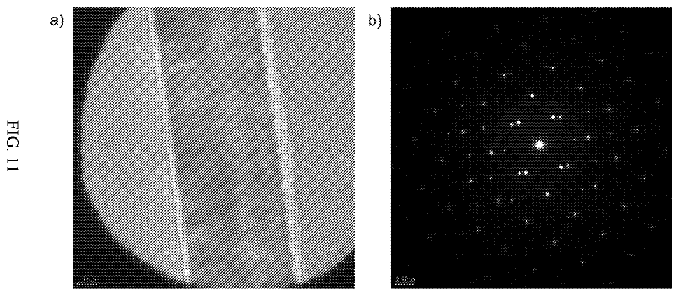

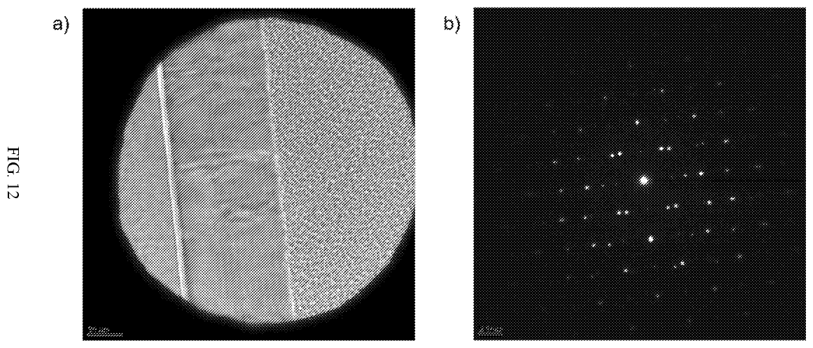

Selected area electron diffraction (SAED) with representative indexed reflections for a BTO₅/STO₅ superstructure is presented in FIG. 6. SAED images taken from the BTO₃/STO₅ and BTO₅/STO₃ superstructures and partial indexation of the SAED image for a BTO₅/STO₃ superstructure can be found at FIGS. 11-13 herein. The c- and a-lattice parameters for BTO and STO sublayers calculated from the positions of (004̅) and (04̅0) diffraction spots from the SAED images for each BTOₓ/STO_{y} superlattice are summarized in Table 2.

TABLE 2
Out-of-plane c-lattice parameter and in-plane
a-lattice parameter for BTO and STO sublayers calculated
from the SAED images for a series of 3 BTOₓ/STO_{y} superstructures
with varying x/y cycle ratio.

| | c-lattice parameter, Å | |
|---|---|---|
| | a-lattice parameter, Å | |
| x/y | BTO | STO |
| 3/5 | 3.96 ± 0.01 | 3.91 ± 0.01 |
| | 3.92 ± 0.01 | 3.92 ± 0.01 |
| 5/5 | 4.03 ± 0.01 | 3.94 ± 0.01 |
| | 3.94 ± 0.01 | 3.92 ± 0.01 |
| 5/3 | 4.04 ± 0.01 | 3.93 ± 0.01 |
| | 3.97 ± 0.01 | 3.92 ± 0.01 |

Interestingly, both c- and a-lattice parameters of BTO sublayer systematically increase, while the parameters of STO remain practically unchanged, as the thickness of BTO layer (or x/y ratio) in the superstructure increases. One can notice that the SAED area includes a large amount of the STO-template layer.

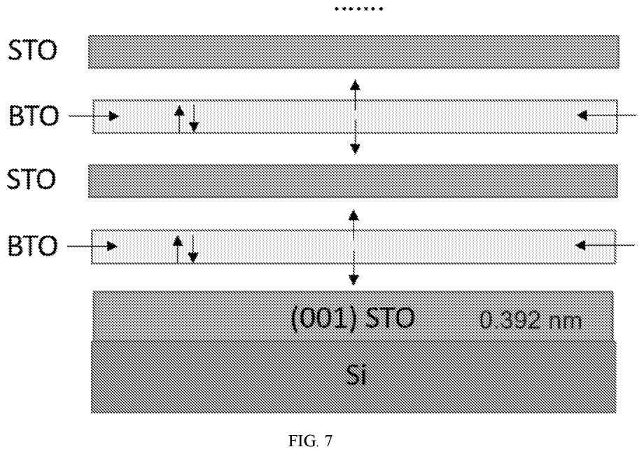

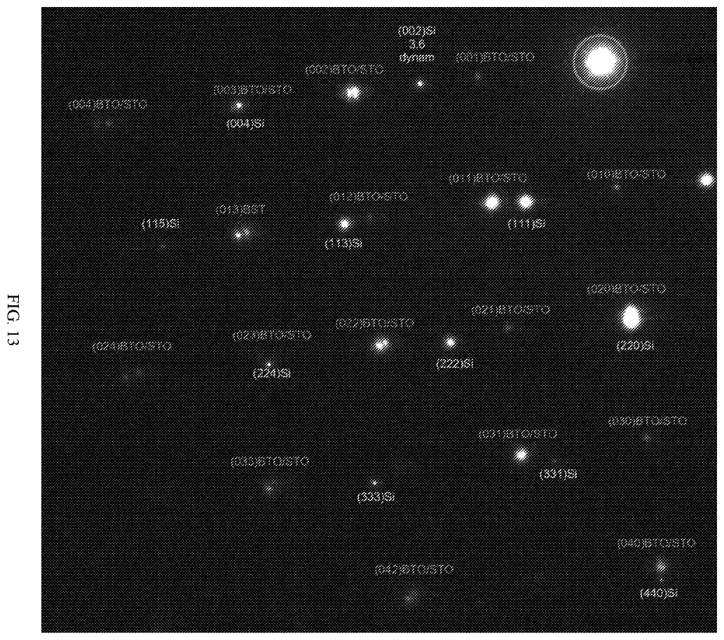

As the contribution from the 18-nm thick STO-template layer to the diffraction pattern is almost the same as that from the STO sublayers, the total thickness of which is 12, 20 and 33.3 nm for the superstructures with x/y=3/5, 5/5 and 5/3, respectively, the lattice parameters for STO in Table 2 can be considered as an averaged value. Furthermore, splitting in STO diffraction spots is not indicated, which means very small or even no difference between the lattice parameters of STO-template layer and STO-sublayer in the superstructure. That said, the STO is almost unstrained, while BTO is under compressive in-plane strain with increasing x/y. These results allow to suggest that the highest compression strain is introduced at the interface between BTO and STO sublayers in the BTO₃/STO₅ superstructure. The tetragonality of BTO increases from c/a=1.01 at x/y=3/5 to c/a=1.022 at x/y=5/5 and then decreases to c/a=1.017 at x/y=5/3. Therefore, the highest out-of-plane polarization is supposed to be in the BTO₅/STO₅ superstructure. The orientation of polarization in the BTO layers and the strained state of the BTOₓ/STO_{y} superstructure are represented in FIG. 7. The reciprocal space map for an asymmetric scan of the (103) peak around the hMBE STO-layer is displayed in FIG. 13, and reveals that the superlattice is fully strained to the crystallization layer. This epitaxial registration to the substrate is very difficult to attain with the commonly used two-step deposition and post-annealing process for ALD-grown complex oxides and is another important factor to induce a high degree of functionality into the ALD-grown film.

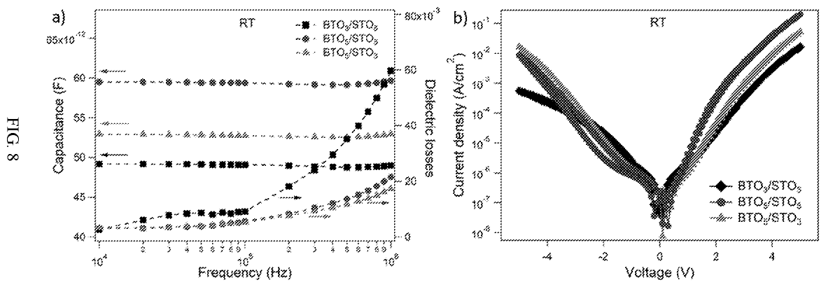

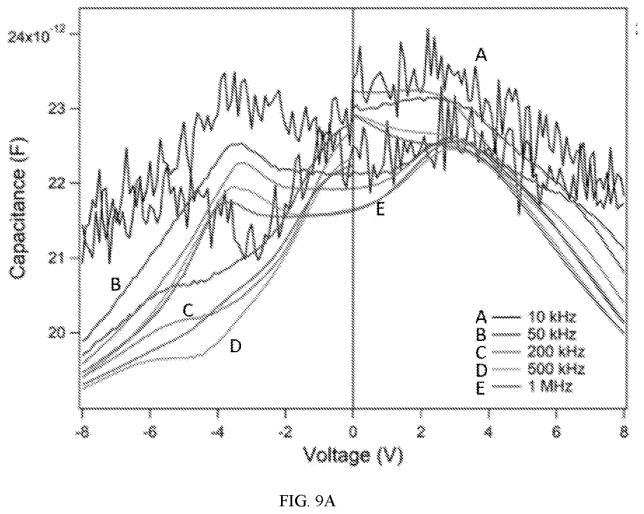

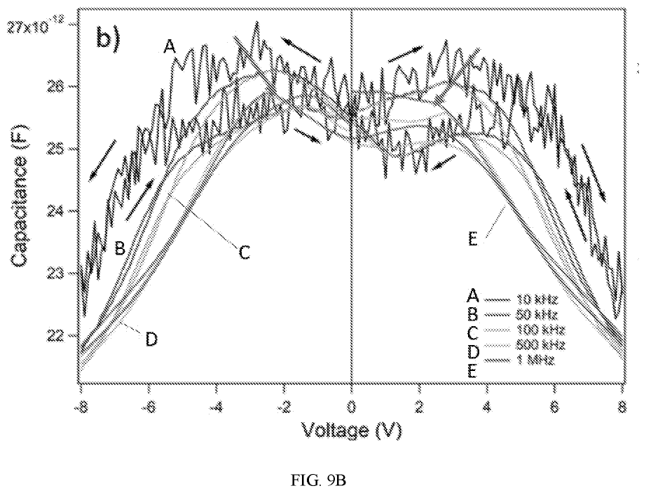

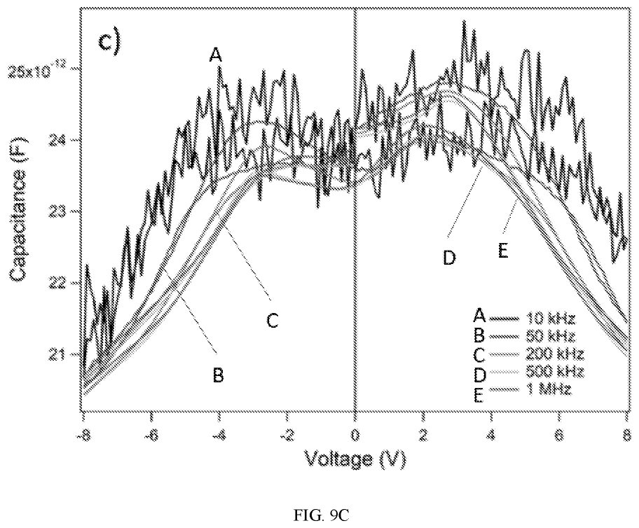

The results of the room temperature dielectric measurements are presented in FIGS. 8 and 9. The capacitance and losses as a function of frequency (FIG. 8a) and I-V dependence (FIG. 8b) were collected in the top-to-bottom geometry. One can notice that the value of the capacitance is observed for the BTO₅/STO₅ superstructure is a factor of 1.2 higher than that for the BTO₃/STO₅ and BTO₅/STO₃ superstructures. Loss is quite low, 0.001-0.002 within 10 kHz-1 MHz frequency range, for the BTO₅/STO₅ and BTO₅/STO₃ superstructures, while it slightly higher, ˜ 0.006 at 1 MHz, for a BTO₃/STO₅ superstructure. Leakage current is relatively low for all films, and is quite symmetric for positive and negative bias.

Interesting C-V dependences as a function of frequency were observed for all BTOₓ/STO_{y} superstructures. This data was collected in top-to-top geometry. Representative dependences are shown in FIG. 9. Black arrows indicate the applied voltage, which was lifted up from 0 to +10 V, down from +10 V to 0 V, and then up from 0 V to −10 V and down from −10 V to 0 V. FIG. 9b demonstrates the most symmetrical C-V dependence among a series of three superstructures. This dependence is collected on the BTO₅/STO₅ superstructure.

A pronounced maximum at low frequency under positive as well as under negative bias, +3.4 V, shifts to lower voltage, +2.4 V, and at the same time decreases in magnitude as the frequency increases from 10 kHz to 1 MHz, respectively. Similar changes in C-V dependences with increasing frequency occur for the BTO₃/STO₅ and BTO₅/STO₃ superstructures. Such a behavior was not observed previously in BTO/STO superlattices, and therefore needs to be further explored.

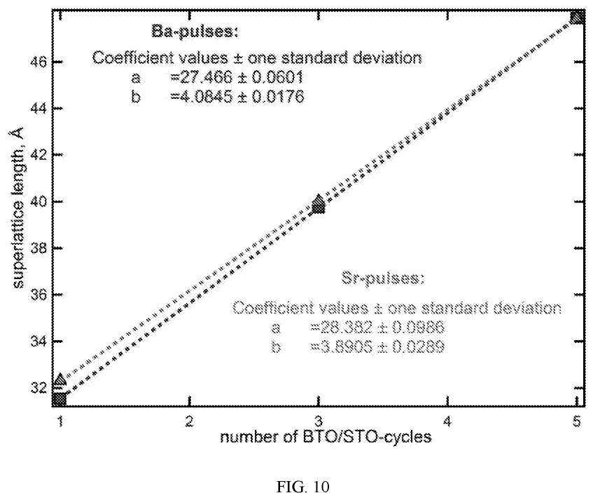

An analysis of the superstructure peaks reveals a systematic change of the superstructure repeat unit thickness with a change in the deposition sequence. The slope for an increasing number of BTO-layers from 1:5, 3:5 to 5:5 (BTO/STO cycles), and vice versa for the STO-layers reveals slopes of 4.08 nm and 3.89 nm, respectively, which are both close to the expected unit cell thicknesses of the individual constituents (see FIG. 10). This observation indicates a minor intermixing of Ba and Sr in the individual layers.

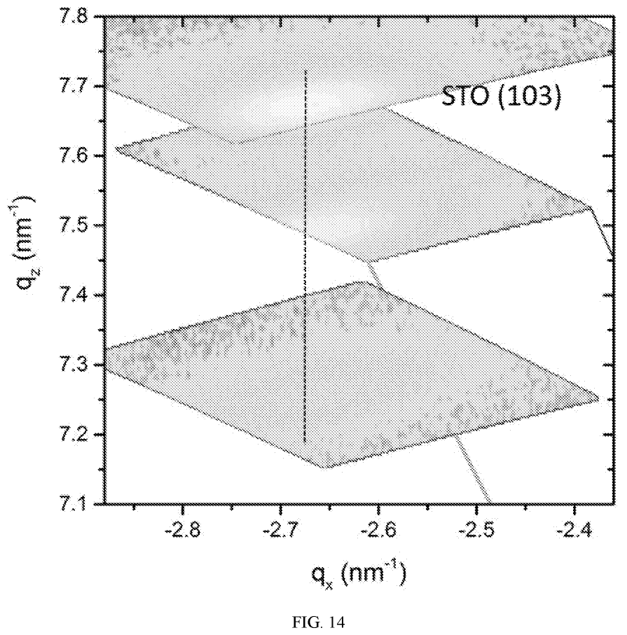

The reciprocal space map for an asymmetric scan of the (103) peak around the hMBE STO-layer is displayed in FIG. 14, and reveals that the superlattice is fully strained to the crystallization layer. This epitaxial registration to the substrate is very difficult to attain with the commonly used two-step deposition and post-annealing process for ALD-grown complex oxides and is another factor to induce a high degree of functionality into the ALD-grown film.

Additional Exemplary Disclosure

In this disclosure is demonstrated the formation of epitaxially oriented BiFeO₃ via separation of crystallization from deposition, i.e., solid phase epitaxy. Films deposited by ALD on (001)-oriented Si utilizing a thin (001)-oriented SrTiO₃ metamorphic buffer layer grown by hybrid-MBE can be achieved at a temperature of 500° C.

An in-situ transmission electron microscopy study provides detailed insight into the crystallization mechanisms during the post-deposition annealing and shows that crystalline regions at the interface to the seed layer were already present in the mostly amorphous Bi—Fe—O film after the atomic layer deposition at 220° C.

Upon further annealing a complex formation process of crystalline BiFeO₃ on the SrTiO₃ template was found, involving crystallization of randomly oriented nanograins, grain reorientation and grain coarsening. Overall, the exemplary annealing process resulted in an epitaxial BiFeO₃ thin film, which is monolithically integrated on (001)-oriented Si under back-end-of-the-line (BEOL)-compatible conditions.

The disclosed non-limiting results are centered around two main points. First, an in-situ transmission electron microscopy (TEM) investigation of the BiFeO₃ thin film crystallization on an 18-nm-thick seed layer of (001)-oriented SrTiO₃ is performed to provide detailed insights into the solid-solid transformation process. Second, we demonstrate the formation of a 60 nm thick epitaxial BiFeO₃ thin film on a metamorphic (001) SrTiO₃/Si substrate as crystallization template to take a step towards scalable integration of functional perovskite oxide thin films into existing technology at the lowest possible thermal budget. Recently, it was shown that La-doped BiFeO₃ integrated in a similar manner on Si-substrates utilizing reactive MBE and PLD exhibits a strain driven antiferroelectric-to-ferroelectric phase transition at the morphotropic phase boundary. A low temperature synthesis route for such thin film heterostructures, where processing steps for the functional layer can be conducted at BEOL-compatible conditions, is thus desirable.

We pursued an ALD approach based on well-intermixed Bi₂O₃ and Fe₂O₃ layers with a nominal average thickness of monoxide layers of less than 10 Å by reducing the repeat numbers of 18 Bi—O and 19 Fe—O subcycles. This strategy is different from previous investigations on the formation and properties of polycrystalline BiFeO₃ thin films grown by ALD, where several nm thick binary layers of Bi₂O₃ and Fe₂O₃ were combined into laminates and transformed into the perovskite during post-deposition annealing.

Here, thin films, which contained 13 Fe₂O₃—Bi₂O₃ constituent layers with a top layer of Fe₂O₃, had a total thickness of 280 Å and were deposited on metamorphic (001)-oriented SrTiO₃/Si substrates. X-ray reflectivity measurements and transmission electron microscopy images in cross sections were taken after deposition and provided no indications of cation segregation into distinct layers. This thorough cation intermixing should promote the homogeneous crystallization of epitaxial BiFeO₃ films due to minimized diffusion requirements and suppressing the formation of larger Bi₂O₃ regions, which were found to partially crystallized at a deposition temperature of 290° C.

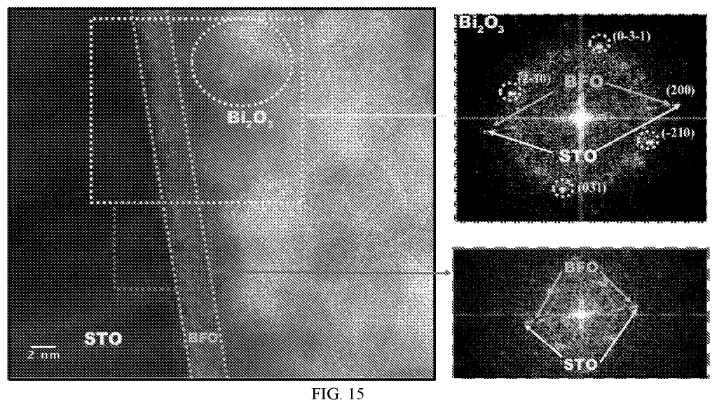

At the initial stage of the in-situ TEM annealing process, the as deposited BiFeO₃ film on the (001)-oriented SrTiO₃/Si substrate was heated up to 250° C., which is 30° C. above the deposition temperature. While the majority of the BiFeO₃ layer remained in the amorphous state, a thin crystalline layer of the ALD-grown BiFeO₃ film at the interphase to the SrTiO₃ layer was already present (FIG. 15). The thickness of this crystalline layer was 2.5 nm. In addition to this interfacial layer, crystalline regions within the film were also observed.

The analysis of the corresponding fast Fourier transform (FFT) spectra revealed that the interfacial layer gave rise to spots corresponding to BiFeO₃ in pseudo-cubic symmetry, crystallographically aligned to the SrTiO₃ seed layer. (FIG. 15, bottom right) This observation implies that the high surface energy of an extremely thin film favors the crystallization already at the deposition temperature of 220° C. However, the thermal energy was too low to establish a crystalline growth front throughout the entire film during the deposition. This could result from a larger density of residual organic impurities or locally insufficient intermixing of Bi- and Fe-cations.

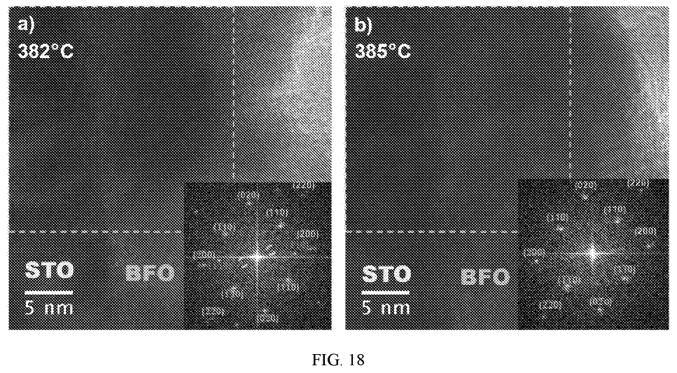

Interestingly, nano-crystalline areas were identified also within the bulk of the film (highlighted by the cyan circle in FIG. 15) with atomic plane distances about 2.5 Å, most likely corresponding to alpha-Bi₂O₃ (FIG. 18 top right, cyan circles). This observation is consistent with our previous study of the crystallization behavior of BFO from Bi₂O₃—Fe₂O₃ superlattices, where most of the several nanometer thick layers of Bi₂O₃ were already crystalline after the deposition, while the Fe₂O₃ layers remained amorphous.

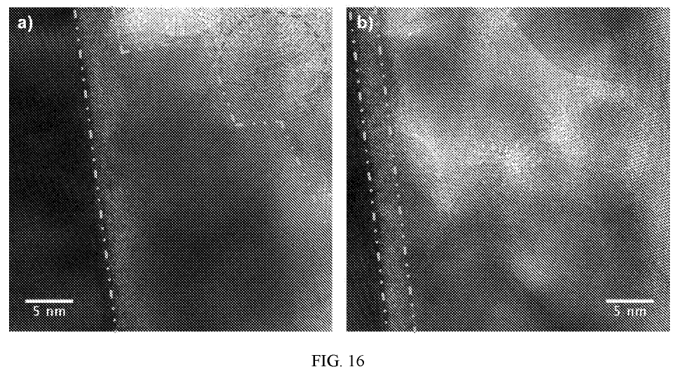

Subsequent heating was performed at a rate of 5° C./min up to 300° C. The ordering in the semi-crystalline sub-layer improved towards the (001)-orientation imposed by the substrate. Starting from the initially ˜2.5-nm-thick layer the crystallization of BiFeO₃ with (001)-orientation progressed into the entire volume of the BiFeO₃ film (FIG. 16a). This grain growth occurred at temperatures lower than expected from the onset of crystallization at a temperature of 450° C. for BiFeO₃ on SrTiO₃ determined from in situ XRD experiments.

Here, however, the geometry of the BiFeO₃ specimen (extremely thin sheet), inhomogeneous temperature distribution for the TEM-sample holder producing local hot spots, local heating by the electron beam, and the different detection limits of TEM and XRD (which typically needs a larger volume of crystalline material to produce sharp Bragg diffraction peaks) could explain this difference. In addition, randomly oriented crystallites nucleated closer to the top of the film, as depicted in FIG. 16. One can speculate that areas of already crystalline Bi₂O₃ and TiO₂ (served as protective layer to eliminate direct contact between Bi and Pt) on the top of the film served as nucleation seeds for the BiFeO₃ grains.

In other regions of the film, where the progression of the interfacial growth front was suppressed, the formation of randomly oriented grains within the bulk of the film was promoted (FIG. 16b). This mixed crystallization was distinctly different from the behavior found for amorphous SrTiO₃ on (001)-oriented SrTiO₃ substrates, where the epitaxial growth of the thin film occurred exclusively via solid phase epitaxy, while nucleation governed the crystallization of amorphous SrTiO₃ on SiO₂/Si substrates.

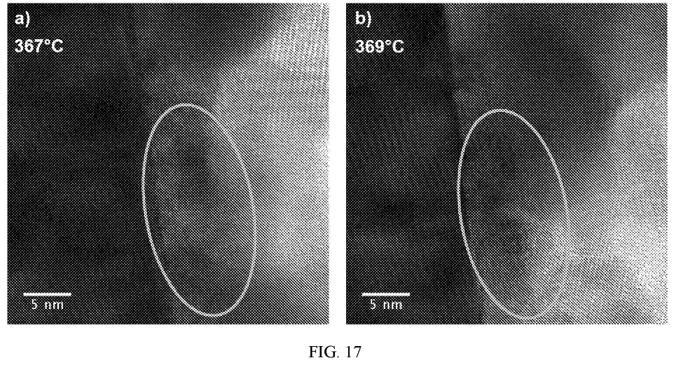

In the following heating sequence the rate was reduced to 2° C./min and was paused at 350° C., 400° C., and 450° C., respectively. Above 350° C. the structural rearrangement of poorly oriented crystallites occurred by aligning towards the epitaxially imposed (001) orientation. The TEM images displayed in FIG. 17a and FIG. 17b were collected at temperatures of 367° C. and 369° C. at the same location of the specimen captured with a one-minute delay. (We estimate error in specimen temperature of ±5° C.) A close comparison of these two images revealed structural rearrangement of atomic columns within the crystallites close to the BiFeO₃—SrTiO₃ interface resulting in the formation of well-ordered BiFeO₃ grains with epitaxial alignment to the substrate.

Structural rearrangement of the BiFeO₃ film started at slightly higher temperatures around 380° C. FIGS. 18a and 18b, which were taken at 382° C. and 385° C., clearly revealed this process, which yielded large epitaxial BiFeO₃ grains at the expense of smaller, misaligned grains. The FFT spectra show spots corresponding to a randomly oriented BiFeO₃ grain which vanished within the small temperature interval of 3° C., highlighting that these small randomly oriented grains were incorporated into epitaxial crystallites, which expanded from the BiFeO₃—SrTiO₃ interface within this very narrow temperature window. This observation implies that this recrystallization process for nanometer-sized grains requires only a small activation energy.

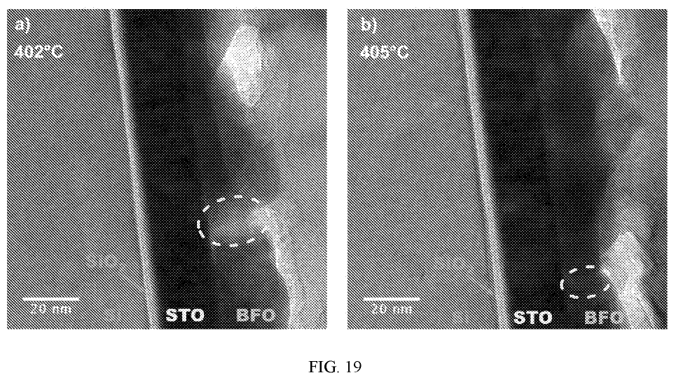

Upon further annealing at temperatures above 400° C., grain growth takes place with large BiFeO₃ grains epitaxially aligned to the SrTiO₃ layer. This mechanism is unveiled by comparing the TEM images displayed in FIG. 19a and FIG. 19b, where the grain boundary between two BiFeO₃ crystallites vanished to form one continuous film between within a small temperature and time interval above 400° C.

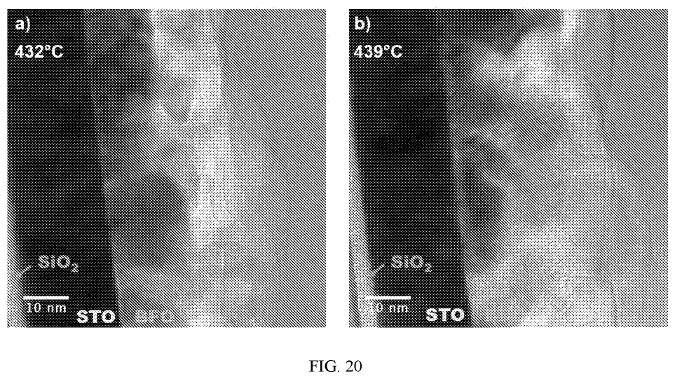

Recrystallization and grain growth continued at even higher temperatures. FIG. 20a (432° C.) and FIG. 20b (439° C.) display a progressing evolution of individual crystallites to a highly oriented thin film approaching the global energy minimum with almost all phase transformations towards epitaxial alignment of large BiFeO₃ grains finishing around 450° C. Noting that the rate of heat dissipation from the e-beam (thermalization of hot injected electrons via coupling to phonons, and subsequent anharmonic phonon-phonon interactions) in our thin film sample geometry is likely to lower the temperature for the solid-solid transformation, these results show that the formation of an epitaxial BiFeO₃ film on an SrTiO₃ seed layer can be realized at or below 500° C. combining hybrid-MBE and ALD methods. This finding has high relevance for industrial applications as both methods provide high potential for scalability and integration into currently existing technology platforms.

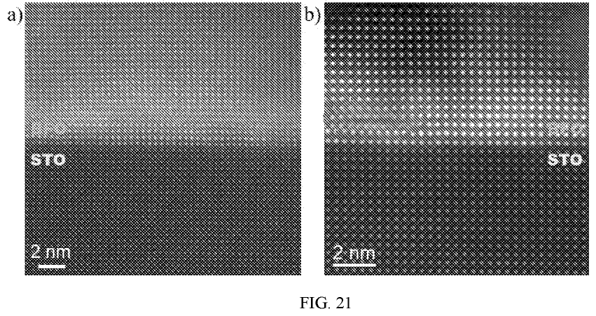

In order to demonstrate that an epitaxial BiFeO₃ film with excellent quality can be achieved via the solid-solid transformation after an ALD-deposition of an amorphous film followed by subsequent annealing at a relatively moderate temperature, we show in FIG. 21a a HAADF-STEM image of a 60 nm thick BiFeO₃ film on a 18 nm thick (001)-oriented SrTiO₃ seed layer after ex situ annealing at 500° C.

A fully coherent interface between the substrate and thin film is present. However, we also observed some areas with local defects close to the epitaxial interface as shown in FIG. 21b). A localized defect is interrupting the alignment of the atomic columns in the BiFeO₃ film over a length scale of ˜ 2 unit cells before the epitaxial film continuous along the c-direction.

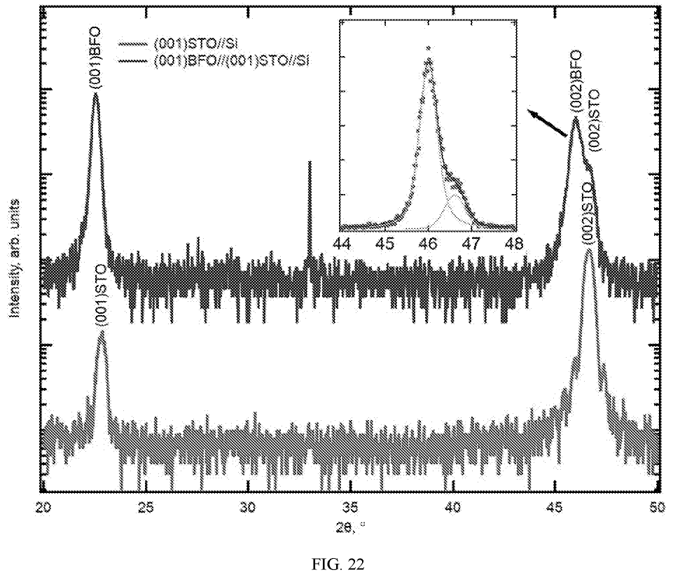

This finding is corroborated by a 0-20 X-ray diffraction (XRD) scan collected for the same film after ex-situ annealing at 500° C. displayed in FIG. 22. The comparison to the XRD-scan of the 18-nm-thick (001)-oriented SrTiO₃ layer on (001)-oriented Si clearly revealed the diffraction peaks corresponding to BiFeO₃ with a c-lattice parameter of 3.94 Å. This value is well within the range typically reported for ALD-grown BiFeO₃ thin films on (001)-oriented SrTiO₃ single crystalline substrates.

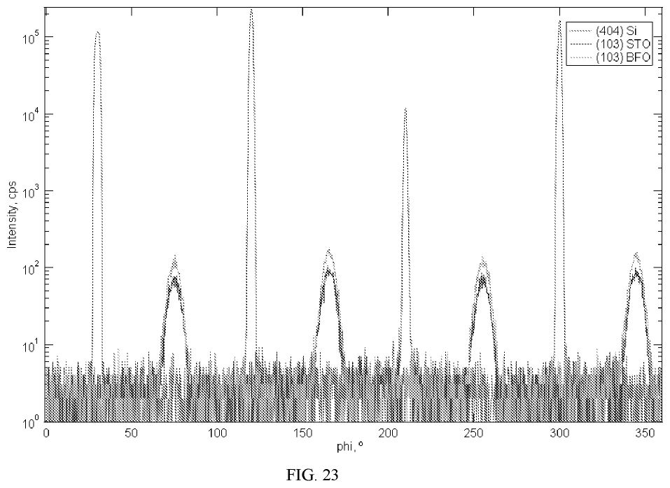

The epitaxial character of BFO thin film is clearly visible on the XRD ϕ-scan (FIG. 23). The BFO pattern completely duplicates STO reflections in position and FWHM of the peaks, with higher intensity, but with the same low noise floor as in the case of Si, indicating that the BFO film fully adopts STO sub-layer topology without any presence of misaligned domains, and that the quality of the BFO films is only limited by the STO sub-layer.

In this disclosure it is shown that the solid-solid transformation of ALD-grown amorphous Bi—Fe—O films into crystalline BiFeO₃ thin films with epitaxial orientation on a (001)-oriented Si substrate can be achieved at temperatures at or below 500° C. utilizing a (001)-oriented SrTiO₃ metamorphic buffer layer grown by hybrid MBE. The combination of these two methods together with the low temperatures required for processing of the BiFeO₃ thin films enables monolithic integration on Si-wafers under back-end-of-line compatible conditions. The in-situ HR-TEM investigation revealed that upon heating the BiFeO₃ layer underwent a very complex crystallization process encompassing phenomena such as reorientation, structural rearrangement, and grain growth. The onset of crystallization occurred at temperatures around 300° C. from a ˜2.5 nm thick epitaxially oriented growth front formed already during the atomic layer deposition.

While this growth front of epitaxially aligned crystallites emerged from the interface with STO and propagated through the film (solid phase epitaxy), randomly oriented BiFeO₃ grains formed simultaneously in the bulk of the film away from the interface. Here, nanocrystalline regions of Bi₂O₃ played a crucial role as seeds, which initialized the formation of these randomly oriented BiFeO₃ grains.

While structural rearrangement to align the BiFeO₃ grains near the interface to the crystallographic orientation of the substrate were observed at 367° C. to 369° C., recrystallization of randomly oriented nanocrystallites required slightly higher temperatures of 382° C. to 385° C. Finally, the merging of larger epitaxially aligned crystallites to reduce the interface energy of the film took place around 400° C. Above 400° C. recrystallization and grain growth continued. Our results indicate that the energy provided by 500° C. is sufficient for the complete transformation of a semi-amorphous ALD-grown Bi—Fe—O layer into a high quality epitaxially oriented BiFeO₃ film on Si-wafers utilizing a thin seed layer of SrTiO₃. Combining these two deposition techniques opens a pathway to monolithic integration of functional perovskite oxides on Si-wafers in a scalable manner.

Methods

Atomic layer depositions (ALD) of Bi—Fe—O thin films were carried out in a Picosun R200 Advanced reactor on (100)-oriented SrTiO₃ and a 20-nm-thick SrTiO₃ layer epitaxially grown on (100)-oriented Si. These metamorphic buffer were grown using a hybrid molecular beam epitaxy (hMBE) technique. The growth of the SrTiO₃ layer is conducted in two steps. First, a 10 monolayer thick template of SrTiO₃ is deposited on an etched Si(100) surface at low temperatures (400-600° C.) by co-supplying elemental Sr and the organometallic Ti-precursor, titanium tetra-isopropoxide (TTIP), from a conventional effusion cell and gas injector, respectively. The initial layer deposition is performed in the absence of additional oxygen, the Ti in the TTIP molecule is tetrahedrally coordinated by oxygen, facilitating the formation of STO on the templated Si surface without forming an amorphous silicon dioxide layer at the interface. After the initial layer formation, growth rates and temperatures can be increased to about 50 nm/hr at 600-900° C.

Amorphous Bi—Fe—O films were deposited on these substrates via ALD at 220° C. using ultra-high purity nitrogen (6N) as carrier gas. Fe(thd)₃ (Iron (III) tris(2,2,6,6-tetramethyl-3,5-heptodionate) synthesized in aqueous solution (˜50% H₂O, ˜50% isopropanol) in a two-step reaction from 2,2,6,6-tetramethyl-3,5-heptodion and ferric nitrate, 9-hydrate, and Bi-triphenyl (Bi(ph)₃, (Alfa Aesar, 99+% purity) were evaporated at source temperatures of 200° C. Ozone in a concentration higher than 200 g/m³ produced by an InUSA generator was used as a reactant for both organometallic precursors supplied to the reaction chamber in a separate line. All films used for the in-situ TEM study were covered by a 100-nm-thick TiO₂ layer, which was also deposited by ALD in order to prevent the interaction of Bi³⁺ ions with the layer of e-beam deposited platinum used for the FIB lift-out. This protective layer was deposited using TTIP and DI water as precursors. The titanium precursor was heated to 115° C., and water was kept at room temperature. The deposition temperature for TiO₂ was 290° C.

All X-ray diffraction (XRD), and X-ray reflectivity measurements (XRR) were performed using a Rigaku Smartlab equipped with a Cu K_{α} radiation source. The cation ratio of the films was measured on a FEI XL30 ESEM equipped with an energy dispersive X-ray spectroscopy (EDS) detector (EDAX) and resulted in a Bi/Fe-ratio of 1:1.

Cross-sectional samples for high resolution transmission electron microscopy were prepared in a Helios (FEI, USA) Scanning Electron Microscope (SEM)/Focus Ion Beam (FIB) dual-beam system equipped with gas injectors for W and Pt deposition and an Omniprobe micromanipulator (Omniprobe, USA) using a standard lift-out procedure. Specimens with a cross-section area of 5×5 μm² were produced and cleaned with 5 keV and 2 keV Ga⁺ ion beams in a final step. These samples were investigated in a Titan 80-300 operating at 300 kV in transmission electron microscopy (TEM) and scanning transmission electron microscopy (STEM) modes. The microscope is equipped with a high-angle annular dark-field (HAADF) detector (Fischione, USA), a spherical aberration (Cₛ) probe corrector and a post-column Gatan energy filter. The images were analyzed with the Digital Micrograph (Gatan, USA) and TEM Imaging and Analysis software (FEI, USA). All TEM measurements were performed in low illumination mode (˜1000 Å/cm² 300 kV) in order to minimize additional heating by the electron beam.

Aspects

In various aspects, the present disclosure pertains to and includes at least the following Aspects. It should be understood that these Aspects are illustrative only and do not necessarily limit the scope of the present disclosure or the appended claims.

Aspect 1. A method for epitaxially integrating a perovskite oxide on a crystalline silicon surface, the method comprising: (a) depositing a crystalline perovskite oxide metamorphic buffer layer onto the crystalline silicon surface; (b) depositing two or more binary metal oxide compounds onto the crystalline perovskite oxide metamorphic buffer layer in order to form a composite structure that includes one or more amorphous metal oxide outer layers on the metamorphic buffer layer; and (c) heating the composite structure for a time and under conditions to allow for the crystallization of each amorphous metal oxide outer layers into an oriented epitaxial perovskite oxide layer.

Aspect 2. The method according to Aspect 1, wherein the crystalline perovskite oxide metamorphic buffer layer has the formula AₓB_{y}O_{3-Δ}, where x is 0.9 to 1.1 and y is 1.1 to 0.9, and 0<Δ<0.1.

Aspect 3. The method of Aspect 2, wherein the A is one or more of Ba, Sr, Bi, La, Ca, Sm, Gd, Lu, Hf, Na, Li, and Pr, and B is one or more of Ti, Fe, Ni, Mn, W, Ru, Nb, Ta, Mo, Sc, and V.

Aspect 4. The method according to any one of Aspects 1-3, wherein the binary metal oxide compounds that form the one or more amorphous metal oxide outer layers respectively have the formula AₓO_{y} and BₓO_{y}, wherein x is 1-2 and y is 1-3.

Aspect 5. The method according to any one of Aspects 1-4, wherein the crystalline perovskite oxide metamorphic buffer layer has a thickness of about 0.1 nm to about 25 nm, about 0.1 to about 20 nm, about 0.5 nm to about 20 nm, about 0.7 nm to about 20 nm, about 1 nm to about 20 nm about 1 nm to about 15 nm, about 1.5 nm to about 15 nm, about 2 nm to about 12 nm, about 5 nm to about 12 nm, about 7 nm to about 12 nm, about 8 nm to about 11 nm, or about 9 nm to about 11 nm, or from 0.1 nm to 0.25 nm, from 0.25 nm to 0.5 nm, from 0.5 nm to 0.75 nm, from 0.75 nm to 1 nm, from 1 nm to 2 nm, from 2 nm to 3 nm, from 3 nm to 4 nm, from 4 nm to 5 nm, from 5 nm to 6 nm, from 6 nm to 7 nm, from 7 nm to 8 nm, from 8 nm to 9 nm, from 9 nm to 10 nm, from 10 nm to 12 nm, from 12 nm to 14 nm, from 14 nm to 16 nm, from 16 nm to 18 nm, from 18 nm to 20 nm, or any combination of two or more of the preceding ranges, for example from 0.3 nm to 18 nm.

Aspect 6. The method according to any one of Aspects 1-5, wherein the crystalline perovskite oxide metamorphic buffer layer is deposited onto the crystalline silicon surface using hybrid molecular beam epitaxy (hMBE).

Aspect 7. The method according to any one of Aspects 1-6, wherein the oriented epitaxial perovskite oxide layer has the formula A′ₓB′_{y}O_{3-Δ}, where x is 0.9 to 1.1 and y is 1.1 to 0.9, and 0<Δ<0.1.

Aspect 8. The method according to Aspect 7 wherein A′ is one or more of Ba, Sr, Bi, La, Ca, Sm, Gd, Lu, Hf, Na, Li, and Pr, and B′ is one or more of Ti, Fe, Ni, Mn, W, Ru, Nb, Ta, Mo, Sc, and V.

Aspect 9. The method according to Aspect 7 or Aspect 8, wherein A is same as A′.

Aspect 10. The method according to any one of Aspects 7-9 wherein B is the same as B′.

Aspect 11. The method according to any one of Aspects 1-10, wherein each amorphous metal oxide outer layer has a thickness that is in a range of from 1 to 2, from 2 to 3, from 3 to 4, from 4 to 5, from 5 to 6, from 6 to 7, from 7 to 8, from 8 to 9, from 9 to 10, from 10 to 12 Å, or the range is defined by any two or more of the preceding ranges.

Aspect 12. The method according to any one of Aspects 1-11, wherein each amorphous metal oxide outer layer has a thickness of about 0.1 to about 10 Å, about 0.2 to about 10 Å, about 0.5 to about 10 Å, about 1 to about 10 Å, about 2 to about 10 Å, about 3 to about 10 Å, about 4 to about 10 Å, about 5 to about 10 Å, about 6 to about 10 Å, about 7 to about 10 Å, about 8 to about 10 Å, about 0.5 to about 9 Å, about 1 to about 9 Å, about 1 to about 8 Å, about 1 to about 7 Å, about 1 to about 6 Å, about 1 to about 5 Å, about 2 to about 8 Å, about 2 to about 7 Å, about 2 to about 6 Å, about 3 to about 6 Å, or about 4 to about 6 Å.

Aspect 13. The method according to any one of Aspects 1-12, wherein each amorphous metal oxide outer layer is deposited by one of atomic layer deposition (ALD), solid phase epitaxy, or epitaxial stabilization, preferably by ALD.

Aspect 14. The method according to any one of Aspects 1-13, wherein the deposition of the two or more binary metal oxide compounds is performed at one or more temperatures in a range of from 70 to 80° C., from 80 to 90° C., from 90 to 100° C., from 100 to 120° C., from 120 to 140° C., from 140 to 160° C., from 160 to 180° C., from 180 to 200° C., from 200 to 220° C., from 220 to 240° C., from 240 to 260° C., from 260 to 280° C., from 280 to 300° C., from 300 to 320° C., from 320 to 340° C., from 340 to 360° C., from 360 to 380° C., from 380 to 400° C., or in a range defined by any two or more of these preceding ranges, for example from 80 to 360° C.

Aspect 15. The method according to any one of Aspects 1-14, wherein the composite structure is heated at a temperature of less than 400° C., such as in a range of from about 250° C. to about 450° C., preferably in a range of from 290° C. or 300° C. to 400° C.

Aspect 16. The method according to any one of Aspects 1-15, wherein the composite structure is heated at a heating rate of from 2° C./min to 10° C./min, between about 250° C. and about 450° C., preferably between about 290° C. or 300° C. to 450° C.

Aspect 17. The method according to any one of Aspects 1-16, further comprising annealing the composite structure at a temperature in a range of from about 400° C. to about 500° C., optionally in a range of from about 400° C. to about 450° C. for a time to allow grain growth in each of the oriented epitaxial perovskite oxide layers.

Aspect 18. The method according to any one of Aspects 1-17, where the heating is accomplished using thermal annealing, rapid thermal annealing, laser annealing, or microwave plasma annealing.

Aspect 19. The method according to any one of Aspects 1-18, wherein the crystalline Si surface is a (001), (100), (110), or (111) oriented crystal.

Aspect 20. The method according to any one of Aspects 1-19, wherein the crystalline perovskite oxide metamorphic buffer layer is a (001), (100), (110), or (111) oriented layer compatible with the crystalline Si surface.

Aspect 21. The method according to any one of Aspects 1-20, wherein the oriented epitaxial perovskite oxide layers are respectively (001), (100), (110), or (111) oriented layers.

Aspect 22. The method according to any one of Aspects 1-21, wherein the crystallization of the amorphous metal oxide outer layers involves one or more of reorientation, recrystallization, and grain growth.

Aspect 23. The method according to any one of Aspects 1-22, wherein crystallization of the amorphous metal oxide outer layers forms nanograins having an average diameter of about 2 to about 100 nm, about 5 to about 100 nm about 10 to about 100 nm, about 10 to about 90 nm, about 20 to about 80 nm, about 30 to about 70 nm, or about 40 to about 60 nm.

Aspect 24. The method according to any one of Aspects 1-23, wherein the oriented epitaxial perovskite oxide layers respectively have a misfit strain level of about −1.0 to about 1%, about −0.5 to about 1%, about −0.25 to about 0.5%, about −0.25 to about 0.25%, or about −1.0, −0.75, −0.5, −0.25, 0, 0.25, 0.5, 0.75, or about 1%, or respectively have a misfit strain level of −1 to −0.5, −0.5 to 0, 0 to 0.5, 0.5 to 1.0%.

Aspect 25. A structure comprising epitaxially integrated perovskite oxide on silicon derived or derivable from the method of any one of the preceding Aspects.

Aspect 26. The structure according to Aspect 25 having a radius of curvature of about 5 to about 100 nm, about 10 to about 80 nm, about 20 to about 70 nm, about 30 to about 60 nm, or about 40 to about 50 nm.

Aspect 27. The structure according to Aspect 25 or Aspect 26 having an aspect ratio of up to 10:1, from 10:1 to 100:1, or from 100:1 to 1000:1.

The disclosures of each patent, patent application, and publication cited or described in this document are hereby incorporated herein by reference, each in its entirety, for all purposes, or at least for the purpose described in the context in which the reference was presented.

### REFERENCES

The following references are presented for the reader's convenience The inclusion of a reference is not an acknowledgement or concession that the reference is in any way material to the patentability of the disclosed technology.
Sujit Das, Anirban Ghosh, Margaret R. McCarter, Shang-Lin Hsu, Yun-Long Tang, Anoop R. Damodaran, R. Ramesh, and Lane W. Martin. Perspective: Emergent topologies in oxide superlattices. APL Mater. 6, 100901 (2018).
Y. Nahas, S. Prokhorenko, L. Louis, Z. Gui, I. Kornev, and L. Bellaiche. Discovery of stable skyrmionic state in ferroelectric nanocomposites. Nat. Commun. 6:8542 doi: 10.1038/ncomms9542 (2015).
K. Kathan-Galipeau, P. P. Wu, Y. L. Li, L. Q. Chen, A. Soukiassian, Y. Zhu, D. A. Muller, X. X. Xi, D. G. Schlom, and D. A. Bonnell. Direct determination of the effect of strain on domain morphology in ferroelectric superlattices with scanning probe microscopy. J. Appl. Phys. 112, 052011 (2012).
D. A. Tenne, A. Bruchhausen, N. D. Lanzillotti-Kimura, A. Fainstein, R. S. Katiyar, A. Cantarero, A. Soukiassian, V. Vaithyanathan, J. H. Haeni, W. Tian, D. G. Schlom, K. J. Choi, D. M. Kim, C. B. Eom, H. P. Sun, X. Q. Pan, Y. L. Li, L. Q. Chen, Q. X. Jia, S. M. Nakhmanson, K. M. Rabe, X. X. Xi. Probing Nanoscale Ferroelectricity by Ultraviolet Raman Spectroscopy. Science 313, 1614-1616 (2006).
Zijian Hong, Anoop R. Damodaran, Fei Xue, Shang-Lin Hsu, Jason Britson, Ajay K. Yadav, Christopher T. Nelson, Jian-Jun Wang, James F. Scott, Lane W. Martin, Ramamoorthy Ramesh, and Long-Qing Chen. Stability of Polar Vortex Lattice in Ferroelectric Superlattices. Nano Lett. 17, 2246-2252 (2017).
Benjamin Bein, Hsiang-Chun Hsing, Sara J. Callori, John Sinsheimer, Priya V. Chinta, Randall L. Headrick, and Matthew Dawber. In situ X-ray diffraction and the evolution of polarization during the growth of ferroelectric superlattices. Nat. Commun. 6:10136 doi: 10.1038/ncomm100136 (2015).
Liu, Y. Y. & Li, J. Y. Space charges and size effects in semiconducting ferroelectric BaTiO3/SrTiO3 superlattices. Appl. Phys. Lett. 97, 042905 (2010).
A. Ohtomo and H. Y. Hwang, A high-mobility electron gas at the LaAlO3/SrTiO3 heterointerface. Nature 427, 423 (2004).
N. Reyren, S. Thiel, A. D. Caviglia, L. FittingKourkoutis, G. Hammerl, C. Richter, C. W. Schneider, T. Kopp, A.-S. R″uetschi, D. Jaccard, M. Gabay, D. A. Muller, J.-M. Triscone, and J. Mannhart, Superconducting Interfaces Between Insulating Oxides. Science 317, 1196 (2007).
H. N. Lee, Hans M. Christen, Matthew F. Chisholm, Christopher M. Rouleau & Douglas H. Lowndes. Strong polarization enhancement in asymmetric three-component ferroelectric superlattices. Nature 433, 395 (2005).
K. Ueda, H. Tabata, and T. Kawai, Ferromagnetism in LaFeO3-LaCrO3 Superlattices. Science 280, 1064 (1998).
Schlom, D. G. et al. Oxide nano-engineering using MBE. Mater. Sci. Eng. B 87, 282-291 (2001).
Yamada, H. et al. Engineered interface of magnetic oxides. Science 305, 646-648 (2004).
Lee, H. N., Christen, H. M., Chisholm, M. F., Rouleau, C. M. & Lowndes, D. H. Thermal stability of epitaxial SrRuO3 films as a function of oxygen pressure. Appl. Phys. Lett. 84, 4107-4109 (2004).
David A. Keller, Adam Ginsburg, Hannah-Noa Barad, Klimentiy Shimanovich, Yaniv Bouhadana, Eli Rosh-Hodesh, Ichiro Takeuchi, Hagit Aviv, Yaakov R. Tischler, Assaf Y. Anderson, and Arie Zaban. Utilizing Pulsed Laser Deposition Lateral Inhomogeneity as a Tool in Combinatorial Material Science. ACS Comb. Sci. 17, 209-216 (2015).
H. Lu, C.-W. Bark, D. Esque de los Ojos, J. Alcala, C. B. Eom, G. Catalan, A. Gruverman. Mechanical Writing of Ferroelectric Polarization. Science 336, 59-61 (2012).
Tang, Y. L., Y. L. Zhu, X. L. Ma, A. Y. Borisevich, A. N. Morozovska, E. A. Eliseev, W. Y. Wang, Y. J. Wang, Y. B. Xu, Z. D. Zhang, and S. J. Pennycook. Observation of a periodic array of flux-closure quadrants in strained ferroelectric PbTiO3. Science 348, 547-551 (2015).
Ming Liu, Chunrui Ma, Gregory Collins, Jian Liu, Chonglin Chen, Andy D Alemayehu, Guru Subramanyam, Ying Ding, Jianghua Chen, Chao Dai, Yuan Lin and Melanie W Cole Ferroelectric BaTiO3/SrTiO3 multilayered thin films for room-temperature tunable microwave elements. Nanoscale Research Letters 8:338 (2013).
Hitoshi Tabata, Hidekazu Tanaka, and Tomoji. Kawai Formation of artificial BaTiO3/SrTiO3 superlattices using pulsed laser deposition and their dielectric properties. Appl. Phys. Lett. 65 (15), 1970-1972 (1994).
Nakagawara O, Shimuta T, Makino T, Arai S, Hitoshi Tabata and Tomoji Kawai. Epitaxial growth and dielectric properties of (111) oriented BaTiO3/SrTiO3 superlattices by pulsed-laser deposition. Appl. Phys. Lett. 77:3257-3259 (2000).
D. G. Schlom, J. H. Haeni, J. Lettieri, C. D. Theis, W. Tian, J. C. Jiang, and X. Q. Pan, “Oxide nanoengineering using MBE,” Mater. Sci. Eng. B 87, 282-291 (2001).
T. Harigai, H. Kimbara, H. Kakemoto, S. Wada, and T. Tsurumi. Temperature Dependence of Dielectric Properties of BaTiO3/SrTiO3 Artificial Superlattices. Ferroelectrics 357:128-132, (2007).
Frangois Weiss, Marc Audier, Ausrine Bartasyte, Daniel Bellet, Cecile Girardot, Carmen Jimenez, Jens Kreisel, Stephane Pignard, Mathieu Salaun, and Celine Ternon. Multifunctional oxide nanostructures by metal-organic chemical vapor deposition (MOCVD). Pure Appl. Chem. 81, 1523-1534 (2009).
Zaiyang WANG, Shunri ODA, M. KARLSTEEN, U. SÖDERVALL and Magnus WILLANDE. Structure Analysis of SrTiO3/BaTiO3 Strained Superlattice Films Prepared by Atomic-Layer Metalorganic Chemical Vapor Deposition. Jpn. J. Appl. Phys. 39, 4164-4167 (2000).
Neil P. Dasgupta, Han-Bo-Ram Lee, Stacey F. Bent, and Paul S. Weiss. Recent Advances in Atomic Layer Deposition. Chem. Mater. 28, 1943-1947 (2016).
H. H. Sonsteby, H. Fjellvåg and O. Nilsen, Functional Perovskites by Atomic Layer Deposition—An Overview. Adv. Mater. Interfaces 4, 1600903 (2017).
M. Falmbigl, I. A. Karateev, I. S. Golovina, A. V. Plokhikh, T. C. Parker, A. L. Vasiliev and J. E. Spanier, Evidence of extended cation solubility in atomic layer deposited nanocrystalline BaTiO3 thin films and its strong impact on the electrical properties. Nanoscale, 2018, 10, 12515.
Iryna S. Golovina, Matthias Falmbigl, Christopher J. Hawley, Anthony Ruffino, Aleksandr V. Plokhikh, Igor A. Karateev, Thomas C. Parker, Alejandro Gutierrez-Perez, Alexandre L. Vasiliev, and Jonathan E. Spanier. Controlling the Phase Transition in Nanocrystalline Ferroelectric Thin Films via Cation Ratio. Nanoscale, 2018, 10, 21798.
J.-H. Kim, J.-Y. Kim and S.-W. Kang, Film growth model of atomic layer deposition for multicomponent thin films. J. Appl. Phys., 2005, 97, 93505.
M. D. McDaniel, T. Q. Ngo, S. Hu, A. Posadas, A. A. Demkov, J. G. Ekerdt, Atomic layer deposition of perovskite oxides and their epitaxial integration with Si, Ge, and other semiconductors. Appl. Phys. Rev. 2015, 2, 041301.
Thong Q. Ngo, Agham B. Posadas, Martin D. McDaniel, Chengqing Hu, John Bruley, Edward T. Yu, Alexander A. Demkov, and John G. Ekerdt. Epitaxial c-axis oriented BaTiO3 thin films on SrTiO3-buffered Si(001) by atomic layer deposition. Applied Physics Letters 104, 082910 (2014).
C. Dubourdieu, J. Bruley, T. M. Arruda, A. Posadas, J. Jordan-Sweet, M. M. Frank, E. Cartier, D. J. Frank, S. V. Kalinin, A. A. Demkov, and V. Narayanan, Switching of ferroelectric polarization in epitaxial BaTiO3 films on silicon without a conducting bottom electrode. Nat. Nanotechnol. 8, 748 (2013).
S. H. Baek, J. Park, D. M. Kim, V. A. Aksyuk, R. R. Das, S. D. Bu, D. A. Felker, J. Lettieri, V. Vaithyanathan, S. S. N. Bharadwaja, N. Bassiri-Gharb, Y. B. Chen, H. P. Sun, C. M. Folkman, H. W. Jang, D. J. Kreft, S. K. Streiffer, R. Ramesh, X. Q. Pan, S. Trolier-McKinstry, D. G. Schlom, M. S. Rzchowski, R. H. Blick, and C. B. Eom, Giant Piezoelectricity on Si for Hyperactive MEMS. Science 334, 958-961 (2011).
J. W. Park, D. F. Bogorin, C. Cen, D. A. Felker, Y. Zhang, C. T. Nelson, C. W. Bark, C. M. Folkman, X. Q. Pan, M. S. Rzchowski, J. Levy, and C. B. Eom, Creation of a two-dimensional electron gas at an oxide interface on silicon. Nat. Commun. 1:94 (2010).
J. Wang, H. Zheng, Z. Ma, S. Prasertchoung, M. Wuttig, R. Droopad, J. Yu, K. Eisenbeiser, and R. Ramesh, Epitaxial BiFeO3 thin films on Si. Appl. Phys. Lett. 85, 2574-2576 (2004).
Asis Sarkar and S. B. Krupanidhi. Ferroelectric interaction and polarization studies in BaTiO3/SrTiO3 superlattice. J. Appl. Phys. 101, 104113 (2007).
B. D. Qu, M. Evstigneev, D. J. Johnson, and R. H. Prince. Dielectric properties of BaTiO3/SrTiO3 multilayered thin films prepared by pulsed laser deposition. Appl. Phys. Lett. 72, 1394-1396 (1998).
Takaaki Tsurumi, Tomoyoshi Ichikawa, Terukiyo Harigai, Hirofumi Kakemoto, and Satoshi Wada. Dielectric and optical properties of BaTiO3/SrTiO3 and BaTiO3/BaZrO3 superlattices. J. Appl. Phys. 91, 2284-2289 (2002).
Alina VISINOIU*, Roland SCHOLZ, Soma CHATTOPADHYAY1, Marin ALEXE and Dietrich HESSE. Formation of Epitaxial BaTiO3/SrTiO3 Multilayers Grown on Nb-Doped SrTiO3 (001) Substrates. Jpn. J. Appl. Phys. 41, 6633-6638 (2002).
Toru Shimuta, Osamu Nakagawara, Takahiro Makino, and Seiichi Arai, Hitoshi Tabata and Tomoji Kawai. Enhancement of remanent polarization in epitaxial BaTiO3/SrTiO3 superlattices with “asymmetric” structure. J. Appl. Phys. 91, 2290-2294 (2002).
Kim T U, Kim B R, Lee W J, Moon J H, Lee B T, Kim J H. Integration of artificial SrTiO3/BaTiO3 superlattices on Si substrates using a TiN buffer layer by pulsed laser deposition method. Journal of Crystal Growth, 289, 540-546 (2006).
S. Abel, T. St€oferle, C. Marchiori, C. Rossel, M. D. Rossell, R. Erni, D. Caimi, M. Sousa, A. Chelnokov, B. J. Offrein, and J. Fompeyrine. A strong electro-optically active lead-free ferroelectric integrated on silicon. Nat. Commun. 4, 1671 (2013).
M. Choi, A. Posadas, R. Dargis, C.-K. Shih, A. A. Demkov, D. H. Triyoso, N. D. Theodore, C. Dubourdieu, J. Bruley, and J. Jordan-Sweet, Strain relaxation in single crystal SrTiO3 grown on Si (001) by molecular beam epitaxy. J. Appl. Phys. 111, 064112 (2012).
Lei Zhang and Roman Engel-Herbert. Growth of SrTiO3 on Si(001) by hybrid molecular beam epitaxy. Phys. Status Solidi RRL, 1-7 (2014).
Matthew Brahlek Arnab Sen Gupta Jason Lapano Joseph Roth Hai-Tian Zhang Lei Zhang Ryan Haislmaier Roman Engel-Herbert. Frontiers in the Growth of Complex Oxide Thin Films: Past, Present, and Future of Hybrid MBE. Adv. Funct. Mater. 1702772 (2017).
Lei Zhang, Yakun Yuan, Jason Lapano, Matthew Brahlek, Shiming Lei, Bernd Kabius, Venkatraman Gopalan, and Roman Engel-Herbert. Continuously Tuning Epitaxial Strains by Thermal Mismatch. ACS Nano 12, 1306-1312 (2018).
Schlom, D. G.; Chen, L.-Q.; Eom, C.-B.; Rabe, K. M.; Streiffer, S. K.; Triscone, J.-M. Strain Tuning of Ferroelectric Thin Films. Annu. Rev. Mater. Res. 2007, 37 (1), 589-626.
Pertsev, N. A.; Tagantsev, A. K.; Setter, N. Phase Transitions and Strain-Induced Ferroelectricity in SrTiO3 Epitaxial Thin Films. Phys. Rev. B 2000, 61, R825-R829.
Haeni, J. H.; Irvin, P.; Chang, W.; Uecker, R.; Reiche, P.; Li, Y. L.; Choudhury, S.; Tian, W.; Hawley, M. E.; Craigo, B.; et al. Room-Temperature Ferroelectricity in Strained SrTiO₃. Nature 2004, 430, 758-761.
Warusawithana, M. P.; Cen, C.; Sleasman, C. R.; Woicik, J. C.; Li, Y.; Kourkoutis, L. F.; Klug, J. A.; Li, H.; Ryan, P.; Wang, L.; et al. A Ferroelectric Oxide Made Directly on Silicon. Science (80-.). 2009, 324, 367-371.
Biegalski, M. D.; Qiao, L.; Gu, Y.; Mehta, A.; He, Q.; Takamura, Y.; Borisevich, A.; Chen, L.-Q. Impact of Symmetry on the Ferroelectric Properties of CaTiO₃ Thin Films. Appl. Phys. Lett. 2015, 106 (16), 162904.
Yang, J.-C.; He, Q.; Yu, P.; Chu, Y.-H. BiFeO₃ Thin Films: A Playground for Exploring Electric-Field Control of Multifunctionalities. Annu. Rev. Mater. Res. 2015, 45, 249-275.
Wang, J.; Neaton, J. B.; Zheng, H.; Nagarajan, V.; Ogale, S. B.; Liu, B.; Viehland, D.; Vaithyanathan, V.; Schlom, D. G.; Waghmare, U. V.; et al. Epitaxial BiFeO₃ Multiferroic Thin Film Heterostructures.Pdf. Science (80-.). 2003, 299, 1719-1722.
Zeches, R. J.; Rossell, M. D.; Zhang, J. X.; Hatt, A. J.; He, Q.; Yang, C.-H.; Kumar, A.; Wang, C. H.; Melville, A.; Adamo, C.; et al. A Strain-Driven Morphotropic Phase Boundary in BiFeO₃. Science (80-.). 2009, 326 (5955), 977-980.
Rossell, M. D.; Erni, R.; Prange, M. P.; Idrobo, J.-C.; Luo, W.; Zeches, R. J.; Pantelides, S. T.; Ramesh, R. Atomic Structure of Highly Strained BiFeO₃ Thin Films. Phys. Rev. Lett. 2012, 108 (4), 047601.
Sando, D.; Agbelele, A.; Daumont, C.; Rahmedov, D.; Ren, W.; Infante, I. C.; Lisenkov, S.; Prosandeev, S.; Fusil, S.; Jacquet, E.; et al. Control of Ferroelectricity and Magnetism in Multi-Ferroic BiFeO₃ by Epitaxial Strain. Philos. Trans. R. Soc. A Math. Phys. Eng. Sci. 2014, 372 (2009), 20120438-20120438.
Sando, D.; Xu, B.; Bellaiche, L.; Nagarajan, V. A Multiferroic on the Brink: Uncovering the Nuances of Strain-Induced Transitions in BiFeO₃. Appl. Phys. Rev. 2016, 3 (1), 011106.
Ueno, R.; Okaura, S.; Funakubo, H.; Saito, K. Crystal Structure and Electrical Properties of Epitaxial BiFeO3 Thin Films Grown by Metal Organic Chemical Vapor Deposition. Jpn. J. Appl. Phys. 2005, 44 (39), L1231-L1233.
Eerenstein, W.; Morrison, F. D.; Dho, J.; Blamire, M. G.; Scott, J. F.; Mathur, N. D. Comment on “‘Epitaxial BiFeO₃ Multiferroic Thin Film Heterostructures.’” Science (80-.). 2005, 307, 1203a.
Saito, K.; Ulyanenkov, A.; Grossmann, V.; Ress, H.; Bruegemann, L.; Ohta, H.; Kurosawa, T.; Ueki, S.; Funakubo, H. Structural Characterization of BiFeO₃ Thin Films by Reciprocal Space Mapping. Jpn. J. Appl. Phys. 2006, 45 (9B), 7311-7314.
Thery, J.; Dubourdieu, C.; Baron, T.; Ternon, C.; Roussel, H.; Pierre, F. MOCVD of BiFeO₃ Thin Films on SrTiO3. Chem. Vap. Depos. 2007, 13 (5), 232-238.
Shelke, V.; Harshan, V. N.; Kotru, S.; Gupta, A. Effect of Kinetic Growth Parameters on Leakage Current and Ferroelectric Behavior of BiFeO₃ Thin Films. J. Appl. Phys. 2009, 106 (10), 1-7.
Chen, D.; Nelson, C. T.; Zhu, X.; Serrao, C. R.; Clarkson, J. D.; Wang, Z.; Gao, Y.; Hsu, S.-L.; Dedon, L. R.; Chen, Z.; et al. A Strain-Driven Antiferroelectric-to-Ferroelectric Phase Transition in La-Doped BiFeO₃ Thin Films on Si. Nano Lett. 2017, acs.nanolett.7b03030.
McDaniel, M. D.; Ngo, T. Q.; Hu, S.; Posadas, A.; Demkov, A. A.; Ekerdt, J. G. Atomic Layer Deposition of Perovskite Oxides and Their Epitaxial Integration with Si, Ge, and Other Semiconductors. Appl. Phys. Rev. 2015, 2 (4), 041301.
Sonsteby, H. H.; Fjellvåg, H.; Nilsen, O. Functional Perovskites by Atomic Layer Deposition—An Overview. Adv. Mater. Interfaces 2017, 4 (8).
Akbashev, A. R.; Chen, G.; Spanier, J. E. A Facile Route for Producing Single-Crystalline Epitaxial Perovskite Oxide Thin Films. Nano Lett. 2014, 14 (1), 44-49.
Coll, M.; Gazquez, J.; Fina, I.; Khayat, Z.; Quindeau, A.; Alexe, M.; Varela, M.; Trolier-McKinstry, S.; Obradors, X.; Puig, T. Nanocrystalline Ferroelectric BiFeO₃ Thin Films by Low-Temperature Atomic Layer Deposition. Chem. Mater. 2015, 27 (18), 6322-6328.
Liu, Y.; Ku, C.; Chiu, S.; Lee, H.; Chen, S. Ultrathin Oriented BiFeO₃ Films from Deposition of Atomic Layers with Greatly Improved Leakage and Ferroelectric Properties. Appl. Mater. Interfaces 2014, 6, 443-449.
Akbashev, A. R.; Plokhikh, A. V.; Barbash, D.; Lofland, S. E.; Spanier, J. E. Crystallization Engineering as a Route to Epitaxial Strain Control. APL Mater. 2015, 3 (10), 106102.
Wei Y.; Hu X.; Liang Y.; Jordan D. C.; Craigo B.; Droopad R.; Yu Z.; Demkov A.; Edwards J L.; Ooms W. J. Mechanism of cleaning Si(100) surface using Sr or SrO for growth of crystalline fims. J. Vac. Sci. Technol. B 2002, 20, 1402.
Brahlek, M.; Gupta, A. Sen; Lapano, J.; Roth, J.; Zhang, H. T.; Zhang, L.; Haislmaier, R.; Engel-Herbert, R. Frontiers in the Growth of Complex Oxide Thin Films: Past, Present, and Future of Hybrid MBE. Adv. Funct. Mater. 2018, 28 (9), 1-41.
Zhang, L.; Yuan, Y.; Lapano, J.; Brahlek, M.; Lei, S.; Kabius, B.; Gopalan, V.; Engel-Herbert, R. Continuously Tuning Epitaxial Strains by Thermal Mismatch. ACS Nano 2018, 12 (2), 1306-1312.
Puttaswamy, M.; Vehkamäki, M.; Kukli, K.; Dimri, M. C.; Kemell, M.; Hatanpää, T.; Heikkilä, M. J.; Mizohata, K.; Stern, R.; Ritala, M.; et al. Bismuth Iron Oxide Thin Films Using Atomic Layer Deposition of Alternating Bismuth Oxide and Iron Oxide Layers. Thin Solid Films 2016, 611, 78-87.
Marchand, B.; Jalkanen, P.; Tuboltsev, V.; Vehkamäki, M.; Puttaswamy, M. Electric and Magnetic Properties of ALD-Grown BiFeO₃ Films. J. Phys. Chem. C 2016, 120, 7313-7322.
Plokhikh, A. V. A. V.; Falmbigl, M.; Golovina, I. S. I. S.; Akbashev, A. R. A. R.; Karateev, I A. I A.; Presnyakov, M. Y. M. Y.; Vasiliev, A. L. A. L.; Spanier, J. E. Formation of BiFeO₃ from a Binary Oxide Superlattice Grown by Atomic Layer Deposition. ChemPhysChem 2017, 18 (15), 1966-1970.
Chen, Y.; Yusuf, M. H.; Guan, Y.; Jacobson, R.; Lagally, M. G.; Babcock, S. E.; Kuech, T. F.; Evans, P. G. Distinct Nucleation and Growth Kinetics of Amorphous SrTiO₃ on (001) SrTiO₃ and SiO₂/Si: A Step toward New Architectures. ACS Appl. Mater. Interfaces 2017, No. 001, acsami.7b12978.
Ritala, M.; Niinisto, J. Industrial Applications of Atomic Layer Deposition. ECS Trans. 2009, 25 (8), 641-652.
Gu, X.; Lubyshev, D.; Batzel, J.; Fastenau, J. M.; Liu, W. K.; Pelzel, R.; Magana, J. F.; Ma, Q.; Rao, V. R. Growth, Characterization, and Uniformity Analysis of 200 Mm Wafer-Scale SrTi03/Si. J. Vac. Sci. Technol. B, Nanotechnol. Microelectron. Mater. Process. Meas. Phenom. 2010, 28 (3), C3A12-C3A16.
Pham, C. D.; Chang, J.; Zurbuchen, M. A.; Chang, J. P. Synthesis and Characterization of BiFeO₃ Thin Films for Multiferroic Applications by Radical Enhanced Atomic Layer Deposition. Chem. Mater. 2015, 27 (21), 7282-7288.
Zhang, L.; Engel-Herbert, R. Growth of SrTiO₃ on Si(001) by Hybrid Molecular Beam Epitaxy. Phys. Status Solidi, rrl 2014, 8, 917-923.

1. A method for epitaxially integrating a perovskite oxide on a crystalline silicon surface, the method comprising
(a) depositing a crystalline perovskite oxide metamorphic buffer layer onto the crystalline silicon surface;
(b) depositing two or more binary metal oxide compounds onto the crystalline perovskite oxide metamorphic buffer layer in order to form a composite structure that includes one or more amorphous metal oxide outer layers on the metamorphic buffer layer;
and
(c) heating the composite structure for a time and under conditions to allow for the crystallization of each amorphous metal oxide outer layers into an oriented epitaxial perovskite oxide layer.

2. The method according to claim 1 wherein the crystalline perovskite oxide metamorphic buffer layer has the formula AₓB_{y}O_{3-Δ}, where x is 0.9 to 1.1 and y is 1.1 to 0.9, and 0<Δ<0.1.

3. The method of claim 2, wherein the A is one or more of Ba, Sr, Bi, La, Ca, Sm, Gd, Lu, Hf, Na, Li, and Pr, and B is one or more of Ti, Fe, Ni, Mn, W, Ru, Nb, Ta, Mo, Sc, and V.

4. The method according to claim 1, wherein the binary metal oxide compounds that form the one or more amorphous metal oxide outer layers respectively have the formula AₓO_{y} and BₓO_{y}, wherein x is 1-2 and y is 1-3.

5. The method according to claim 1, wherein the crystalline perovskite oxide metamorphic buffer layer has a thickness of about 0.1 nm to about 25 nm.

6. The method according to claim 1, wherein the crystalline perovskite oxide metamorphic buffer layer is deposited onto the crystalline silicon surface using hybrid molecular beam epitaxy (hMBE).

7. The method according to claim 1, wherein the oriented epitaxial perovskite oxide layer has the formula A′ₓB′_{y}O_{3-Δ}, where x is 0.9 to 1.1 and y is 1.1 to 0.9, and 0<Δ<0.1.

8. The method according to claim 7, wherein A′ is one or more of Ba, Sr, Bi, La, Ca, Sm, Gd, Lu, Hf, Na, Li, and Pr, and B′ is one or more of Ti, Fe, Ni, Mn, W, Ru, Nb, Ta, Mo, Sc, and V.

9. The method according to claim 7, wherein A is same as A′.

10. The method according to claim 7, wherein B is the same as B′.

11. The method according to claim 1, wherein each amorphous metal oxide outer layer has a thickness that is in a range of from 1 to 2, from 2 to 3, from 3 to 4, from 4 to 5, from 5 to 6, from 6 to 7, from 7 to 8, from 8 to 9, from 9 to 10, from 10 to 12 Å, or the range is defined by any two or more of the preceding ranges.

12. The method according to claim 1, wherein each amorphous metal oxide outer layer has a thickness of about 0.1 to about 10 Å.

13. The method according to claim 1, wherein each amorphous metal oxide outer layer is deposited by one of atomic layer deposition (ALD), solid phase epitaxy, or epitaxial stabilization.

14. The method according to claim 1, wherein the deposition of the two or more binary metal oxide compounds is performed at one or more temperatures in a range of from 70 to 80° C., from 80 to 90° C., from 90 to 100° C., from 100 to 120° C., from 120 to 140° C., from 140 to 160° C., from 160 to 180° C., from 180 to 200° C., from 200 to 220° C., from 220 to 240° C., from 240 to 260° C., from 260 to 280° C., from 280 to 300° C., from 300 to 320° C., from 320 to 340° C., from 340 to 360° C., from 360 to 380° C., from 380 to 400° C., or in a range defined by any two or more of these preceding ranges.

15. The method according to claim 1, wherein the composite structure is heated at a temperature of less than 400° C.

16. The method according to claim 1, wherein the composite structure is heated at a heating rate of from 2° C./min to 10° C./min, between about 250° C. and about 450° C.

17. The method according to claim 1, further comprising annealing the composite structure at a temperature in a range of from about 400° C. to about 500° C. for a time to allow grain growth in each of the oriented epitaxial perovskite oxide layers.

18. The method according to claim 1, where the heating is accomplished using thermal annealing, rapid thermal annealing, laser annealing, or microwave plasma annealing.

19. The method according to claim 1, wherein the crystalline Si surface is a (001), (100), (110), or (111) oriented crystal.

20. The method according to claim 1, wherein the crystalline perovskite oxide metamorphic buffer layer is a (001), (100), or (111) oriented layer compatible with the crystalline Si surface.

21. The method according to claim 1, wherein the oriented epitaxial perovskite oxide layers are respectively (001), (100), (110), or (111) oriented layers.

22. The method according to claim 1, wherein the crystallization of the amorphous metal oxide outer layers involves one or more of reorientation, recrystallization, and grain growth.

23. The method according to claim 1, wherein (a) crystallization of the amorphous metal oxide outer layers forms nanograins having an average diameter of about 2 to about 100 nm, (b) the oriented epitaxial perovskite oxide layers respectively have a misfit strain level of about −1.0 to about 1%, or both (a) and (b).

24. The method according to claim 1, wherein the oriented epitaxial perovskite oxide layers respectively have a misfit strain level of about −1.0 to about 1.

25. A structure comprising epitaxially integrated perovskite oxide on silicon derived or derivable from the method of claim 1.

26. The structure according to claim 25 having a radius of curvature of about 5 to about 100 nm.

27. The structure according to claim 25, having an aspect ratio of up to 10:1, from 10:1 to 100:1, or from 100:1 to 1000:1.
